(19) United States
(12) Patent Application Publication
(10) Pub. No.: US 2024/0113165 A1
(43) Pub. Date: Apr. 4, 2024

(54) SEMICONDUCTOR DEVICE

(71) Applicant: Taiwan Semiconductor Manufacturing Company, Ltd., Hsinchu (TW)

(72) Inventors: Ta-Chun LIN, Hsinchu (TW); Chun-Sheng Liang, Changhua County (TW); Chih-Hao Chang, Hsin-Chu (TW); Jhon Jhy Liaw, Hsinchu County (TW)

(73) Assignee: Taiwan Semiconductor Manufacturing Company, Ltd., Hsinchu (TW)

(21) Appl. No.: 18/152,169

(22) Filed: Jan. 10, 2023

Related U.S. Application Data
(60) Provisional application No. 63/411,641, filed on Sep. 30, 2022.

(51) Int. Cl. H01L 29/06; H01L 29/423; H01L 29/775; H01L 29/78; H01L 29/786

(52) U.S. Cl. CPC H01L 29/0673; H01L 29/42392; H01L 29/775; H01L 29/7851; H01L 29/78696

(57) ABSTRACT

A semiconductor device includes a substrate, a first stack of semiconductor nanosheets, a second stack of semiconductor nanosheets, a gate structure and a first dielectric wall. The substrate includes a first fin and a second fin. The first stack of semiconductor nanosheets is disposed on the first fin. The second stack of semiconductor nanosheets is disposed on the second fin. The gate structure wraps the first stack of semiconductor nanosheets and the second stack of semiconductor nanosheets. The first dielectric wall is disposed between the first stack of semiconductor nanosheets and the second stack of semiconductor nanosheets. The first dielectric wall includes at least one neck portion between adjacent two semiconductor nanosheets of the first stack.

### CROSS-REFERENCE TO RELATED APPLICATION

This application claims the priority benefit of U.S. provisional application Ser. No. 63/411,641, filed on Sep. 30, 2022. The entirety of the above-mentioned patent application is hereby incorporated by reference herein and made a part of this specification.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 10C illustrate varying views of a method of forming a semiconductor device in accordance with some embodiments.

FIG. 11 illustrates a view of a cross-sectional view of a semiconductor device in accordance with some embodiments.

FIG. 12 to FIG. 15 illustrate varying views of a method of forming a semiconductor device in accordance with some embodiments.

FIG. 16 illustrates a view of a cross-sectional view of a semiconductor device in accordance with some embodiments.

FIG. 17 to FIG. 20 illustrate varying views of a method of forming a semiconductor device in accordance with some embodiments.

FIG. 21 to FIG. 26 illustrate varying views of a method of forming a semiconductor device in accordance with some embodiments.

FIG. 27 to FIG. 31 illustrate varying views of a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Embodiments of the present disclosure may be used to form gate stacks suitable for use in planar bulk metal-oxide-semiconductor field-effect transistors (MOSFETs), multi-gate transistors (planar or vertical) such as forksheet FET devices, FinFET devices, gate-all-around (GAA) devices, Omega-gate (a-gate) devices, or Pi-gate (H-gate) devices, as well as strained-semiconductor devices, silicon-on-insulator (SOI) devices, partially-depleted SOI devices, fully-depleted SOI devices, or other devices as known in the art. In addition, embodiments disclosed herein may be employed in the formation of p-type and/or n-type devices. One of ordinary skill may recognize other embodiments of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

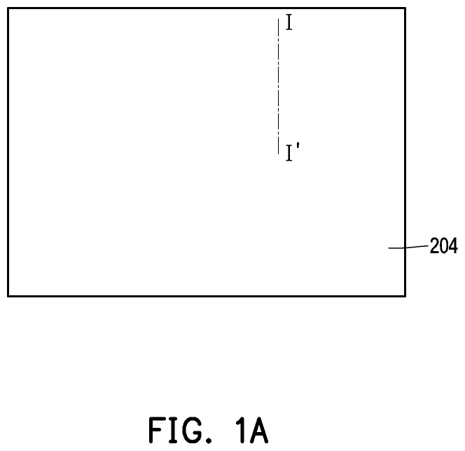

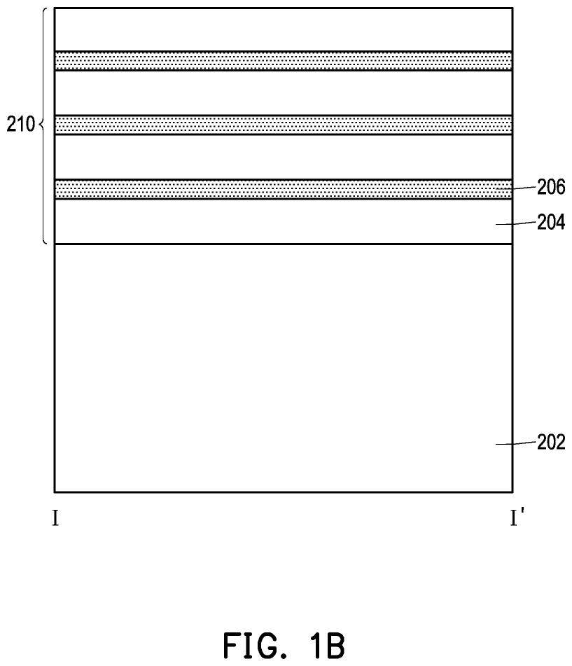

FIG. 1A to FIG. 10C illustrate varying views of a method of forming a semiconductor device in accordance with some embodiments. The semiconductor device illustrated in the following embodiments may be, but not limited to, a multi-gate device. As used herein, the term “multi-gate device” is used to describe a device (e.g., a semiconductor transistor) that has at least some gate material disposed on multiple sides of at least one channel of the device. In some examples, the multi-gate device is also referred to as a gate-all-around (GAA) device having a gate material disposed on four sides of at least one channel member of the device. The channel member may be referred to as “nanosheet” or “nanowire” which is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example but not limited to, a cylindrical in shape or substantially rectangular cross-section. The method is merely an example, and is not intended to limit the present disclosure beyond what is explicitly recited in the claims. Additional steps may be provided before, during, and after method, and some of the steps described can be moved, replaced, or eliminated for additional embodiments of method. Additional features may be added in the semiconductor device depicted in FIG. 1A to FIG. 10C and some of the features described below can be replaced, modified, or eliminated in other embodiments of the semiconductor device.

FIG. 1A to FIG. 4A illustrate top views of stages of forming a semiconductor device, and FIG. 1B to FIG. 4B illustrate cross-sectional views taken along lines I-I′ of FIG. 1A to FIG. 4A. Referring to FIG. 1A and FIG. 1B, a substrate 202 is provided. In some embodiments, the substrate 202 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GalnAs, GaInP and GaInAsP or a combination thereof. The substrate 202 may include various doped regions (e.g., p-type well and/or n-type well) depending on design requirements. In some embodiments, the doped regions are doped with p-type or n-type dopants. The doped regions may be configured for an n-type device, or alternatively, configured for a p-type device. In some embodiments, an anti-punch-through (APT) implantation is performed on a top portion of the substrate 202 to form an APT region. The conductivity type of the dopants implanted in the APT region is the same as that of the doped regions (or wells). The APT region may extend under the subsequently formed strained layers, and are used to reduce the leakage from the strained layers to the substrate 202. The strained layers are referred to “source/drain regions” in some examples. Source/drain region(s) may refer to a source or a drain, individually or collectively dependent upon the context. For clarity, the doped regions and the APT region are not illustrated in FIG. 1A and FIG. 1B and subsequent drawings.

In some embodiments, a semiconductor stack 210 is formed over the substrate 202. The semiconductor stack 210 includes first blanket layers 204 and second blanket layers 206 stacked alternately. The first and second blanket layers are referred to as “first and second layers”, “first and second materials”, “first and second compositions” or “first and second semiconductor materials” in some examples. As described in more detail below, the second blanket layer 206 may serve as channel region(s) for a subsequently formed multi-gate device and its thickness chosen based on device performance considerations. The first blanket layer 204 may be configured to define a gap between adjacent channel region(s) for a subsequently formed multi-gate device and its thickness chosen based on device performance considerations.

The first blanket layers 204 and second blanket layers 206 include different materials. The first blanket layers 204 and the second blanket layers 206 have materials with different etching selectivity. In some embodiments, the first blanket layers 204 are SiGe layers having a germanium percentage in the range between about 15 wt % and 40 wt %, and the second blanket layers 206 are Si layers free of germanium. In other embodiments, either of the first blanket layers 204 and second blanket layers 206 may include other materials such as germanium, a compound semiconductor (e.g., silicon carbide, gallium arsenide, gallium phosphide, indium phosphide, indium arsenide, or indium antimonide), an alloy semiconductor (e.g., SiGe, GaAsP, AlInAs, AlGaAs, InGaAs, GaInP, or GaInAsP), the like, or a combination thereof. The second blanket layers 206 may be of first conductive type (e.g., n-type) or second conductive type (e.g., p-type).

In some embodiments, the first blanket layers 204 and the second blanket layers 206 are formed by an epitaxial growth process, such as a molecular beam epitaxy (MBE) process, a metalorganic chemical vapor deposition (MOCVD) process, or the like. In the case, the first blanket layers 204 are epitaxial SiGe layers, and the second blanket layers 206 are epitaxial Si layers. In some embodiments, the first and second blanket layers 204 and 206 are substantially dopant-free (i.e., having an extrinsic dopant concentration from about 0 cm⁻³ to about 1×10¹⁷ cm⁻³), where for example, no intentional doping is performed during the epitaxial growth process. In other embodiments, the first blanket layers 204 and the second blanket layers 206 are formed by a suitable deposition, such as chemical vapor deposition (CVD), atomic layer deposition (ALD), or the like. In the case, the first blanket layers 204 are poly-SiGe layers, and the second blanket layers 206 are poly-Si layers. In some embodiments, each of the first blanket layers 204 and the second blanket layers 206 has a thickness ranging from about 5 nm to about 15 nm.

In the illustrated embodiment, the bottom layer and the top layer of the semiconductor stack 210 are the first blanket layers 204. However, the disclosure is not limited thereto. In other embodiments (not shown), the bottom layer of the semiconductor stack 210 is the second blanket layer 206 and the top layer of the semiconductor stack 210 is the first blanket layer 204. It is noted that four layers of first blanket layers 204 and three layers of second blanket layers 206 are illustrated in FIG. 1B, which is for illustrative purposes only and not intended to be limiting beyond what is specifically shown in the drawings. Specifically, any number of epitaxial layers may be formed in the semiconductor stack 210; the number of layers depending on the desired number of channel regions for the semiconductor device.

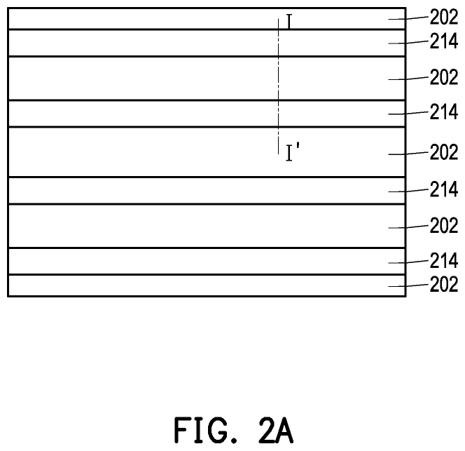

Referring to FIG. 2A and FIG. 2B, the semiconductor stack 210 is patterned to form a plurality of semiconductor strips 220. In some embodiments, a mask layer (not shown) is formed on the semiconductor stack 210. The mask layer may include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. In some embodiments, the mask layer includes a first mask layer and a second mask layer over the second mask layer. For example, the first mask layer is a pad oxide layer made of a silicon oxide, which may be formed by a thermal oxidation. The second mask layer is made of a silicon nitride (SiN), which is formed by chemical vapor deposition (CVD), low pressure CVD (LPCVD), plasma enhanced CVD (PECVD), physical vapor deposition (PVD), atomic layer deposition (ALD), or a suitable process. The mask layer is then patterned into a plurality of mask strips (not shown) by using photolithography and etch processes.

Then, the semiconductor stack 210 and the substrate 202 are patterned by using the mask strips as a mask, so as to form the semiconductor strips 220 separated by trenches T. The patterning process includes an etch process, such as a dry etching or the like. As shown in FIG. 2B, the trenches T extend into the substrate 202, and have lengthwise directions parallel to each other. Herein, the semiconductor strips 220 are referred to as “hybrid fins” in some examples. In some embodiments, each of the semiconductor strips 220 includes a fin 203 protruding from the substrate 202, and a nanosheet stack 212 on the fin 203. In some embodiments, the nanosheet stack 212 includes first nanosheets 214 and second nanosheets 216 stacked alternately. The nanosheets are referred to as “nanowires” or “semiconductor nanosheets” in some examples. In some embodiments, the first nanosheets 214 are referred to as “sacrificial portions”, “dummy portions” or “dummy regions” which will be subsequently removed and replaced by a metal gate structure, and the second nanosheets 216 are referred to as “channel members”, “channel portions” or “channel regions” which will serve as semiconductor channels. Although only two semiconductor strips 220 are illustrated in FIG. 2A and FIG. 2B, the embodiments of the present disclosure are not limited thereto. In other embodiments, the number of the semiconductor strips 220 may be adjusted as needed. The adjacent semiconductor strips 220 may have the same width or different widths.

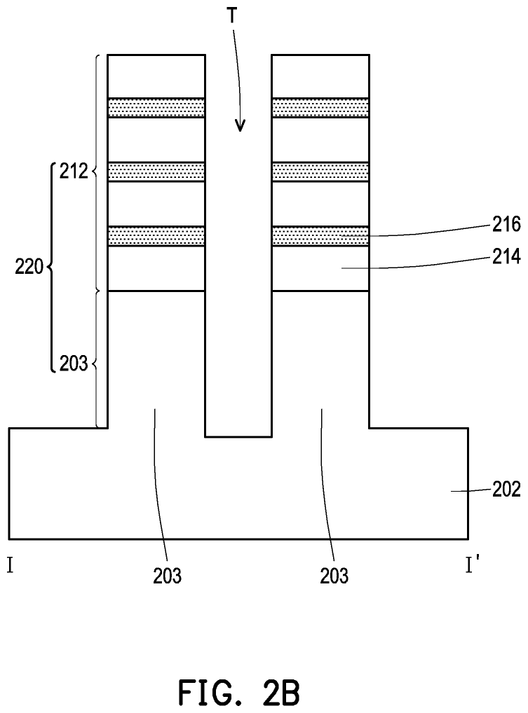

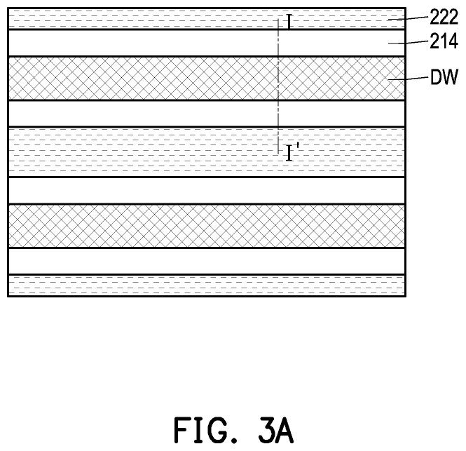

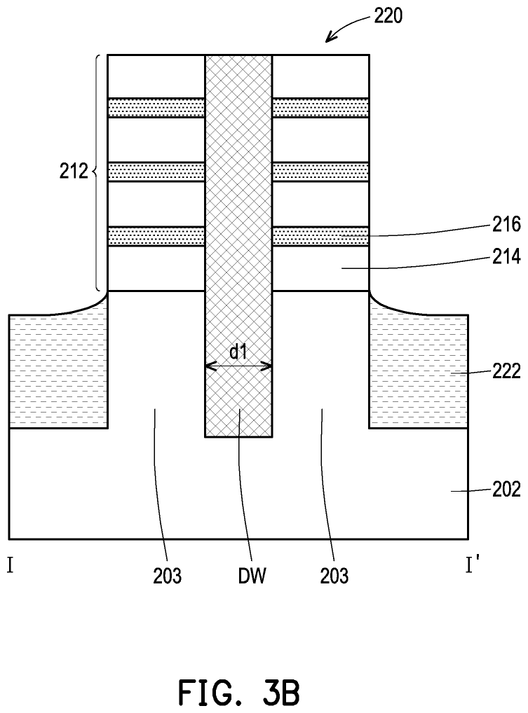

Referring to FIG. 3A and FIG. 3B, dielectric walls DW and insulating regions 222 are alternately formed in the trenches T between the semiconductor strips 220. The insulating regions 222 may be formed before or after the formation of the dielectric walls DW. In some embodiments, the dielectric walls DW and the insulating regions 222 have different materials. The dielectric walls DW may include a dielectric material, such as silicon oxide, silicon nitride, SiON, SiC, SiCN, SiCO, SiCON, a high-k material, the like, or a combination thereof. The high-k material includes metal oxide, such as HfO₂, HfSiO, HfSiON, HfTaO, HfSiO, HfZrO, zirconium oxide, aluminum oxide (Al₂O₃ or AlSiOₓ), titanium oxide, hafnium dioxide-alumina (HfO₂—Al₂O₃) alloy, the like, or combinations thereof. The high-k material has a dielectric constant less than 8, less than 15, less than 20, or even more. Other materials such as a low-k material may be applicable, which mitigates electrical coupling between n-type and p-type strained layers. The low-k material has a dielectric constant less than 3.9, less than 3, less than 2.5, or even less. The dielectric wall DW has a single-layer structure or a multi-layer structure. For example, the dielectric wall DW has multi-layer structure for low-K and breakdown voltage. The insulating regions 222 may include silicon oxide, silicon nitride, silicon oxynitride, a spin-on dielectric material, or a low-k material. The low-k material has a dielectric constant less than 3.9, less than 3, less than 2.5, or even less.

The dielectric walls DW and the insulating regions 222 may be formed by flowable chemical vapor deposition (FCVD), high-density-plasma chemical vapor deposition (HDP-CVD), sub-atmospheric CVD (SACVD), or spin-on process. A planarization process may be performed to remove a portion of the material of the dielectric walls DW, until the semiconductor strips 220 are exposed. In some embodiments, the planarization process includes a chemical mechanical polish (CMP), an etch process such as an etch back process, the like, or a combination thereof. In alternative embodiments, the dielectric wall material is formed in the trenches T and covers top surfaces of the semiconductor strips 220 using a self-aligned process, and the dielectric wall material is partially removed to expose the semiconductor strips 220 and some of the trenches T using an etch process. In some embodiments, as shown in FIG. 3B, top surfaces of the dielectric walls DW are substantially coplanar with the top surfaces of the semiconductor strips 220. The dielectric walls DW may have a horizontal dimension (e.g., width) d1 ranging from about 10 nm to about 40 nm.

In some embodiments, after the formation of the dielectric walls DW, the insulating regions 222 are formed in the exposed trenches T. In some embodiments, the insulating regions 222 are recessed, until the semiconductor strips 220 protrude from top surfaces of the remaining insulating regions 222. Specifically, after the recessing operation, the top surfaces of the insulating regions 222 are lower than the top surfaces of the semiconductor strips 220 and the nanosheet stacks 212 are exposed by the insulating regions 222. In some embodiments, the top surfaces of the insulating regions 222 are also lower than the top surfaces of the dielectric walls DW. The top surfaces of the insulating regions 222 may be substantially coplanar with or lower than bottom surfaces of the nanosheet stacks 212 (e.g., top surfaces of the fins 203). Further, the top surfaces of the insulating regions 222 may have a flat surface, a convex surface, a concave surface (such as dishing), or a combination thereof. In some embodiments, the insulating regions 222 are recessed by using an appropriate etch process, such as a wet etch process with hydrofluoric acid (HF), a dry etch process, or a combination thereof. In some embodiments, a height difference between the top surfaces of the semiconductor strips 220 and the top surfaces of the insulating regions 222 ranges from about 30 nm to about 100 nm. The insulating regions 222 are referred to as “isolation strips”, “shallow trench isolation (STI) regions” or “deep trench isolation (DTI) regions” in some examples. In alternative embodiments in which the dielectric walls DW is formed after the formation of the insulating regions 222, the dielectric wall DW is formed on the insulating region 222 between the fins 203. For example, the insulating regions 222 are respectively formed in the trenches T between the fins 203, and then the dielectric wall DW is formed on the insulating region 222. In such embodiments, a top surface of the insulating region 222 (i.e., bottom surface of the dielectric wall DW) is substantially coplanar with the fin 203.

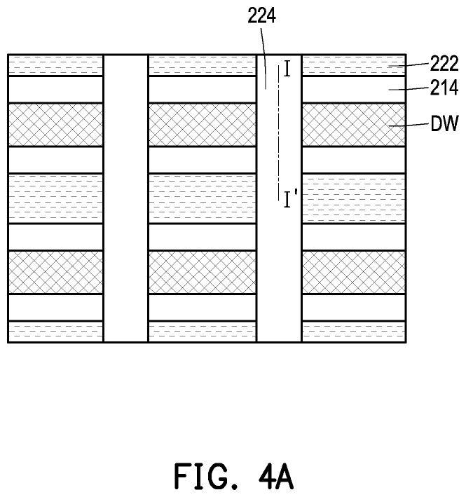

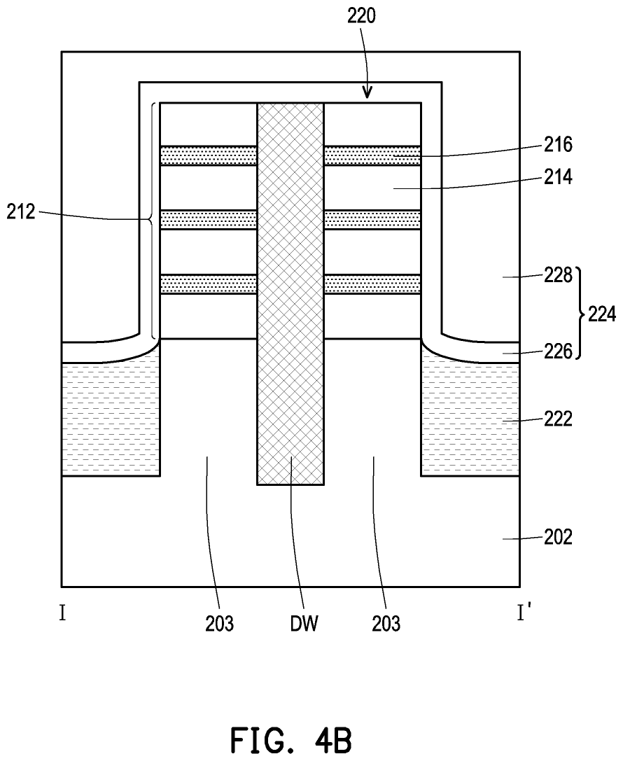

Referring to FIG. 4A and FIG. 4B, after formation of the dielectric walls DW and the insulating regions 222, at least one dummy gate stack 224 is formed across portions of the dielectric walls DW, the nanosheet stacks 212 and the insulating regions 222. The dummy gate stack 224 may extend along a direction different from (e.g., perpendicular to) the extending direction of the nanosheet stacks 212. The dummy gate stack 224 defines the channel regions of the GAA device. The dummy gate stack 224 includes a dummy gate dielectric layer 226 and a dummy gate electrode layer 228 over the dummy gate dielectric layer 226. In some embodiments, a dummy gate dielectric material and a dummy gate electrode material are blanket-formed over the semiconductor strips 220. The dummy gate dielectric material includes silicon oxide such as low temperature oxide (LTO), silicon nitride, silicon oxynitride, high-k dielectrics, or a combination thereof. In some embodiments, the dummy gate electrode material has an etching selectivity with respect to the second nanosheets 216. For example, the dummy gate electrode material includes polysilicon. The dummy gate dielectric material and the dummy gate electrode material are deposited using CVD, LPCVD, PECVD, PVD, ALD, or a suitable process. A mask layer (not shown) may be formed over the dummy gate electrode material. The mask layer may include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. In some embodiments, the mask layer includes a first mask layer (e.g., silicon oxide layer) and a second mask layer (e.g., silicon nitride layer) over the first mask layer. Thereafter, the dummy gate dielectric material and dummy gate electrode material are patterned into the dummy gate stack 224 by using the mask layer as a mask. The mask layer is regarded as part of the dummy gate stack 224 in some examples.

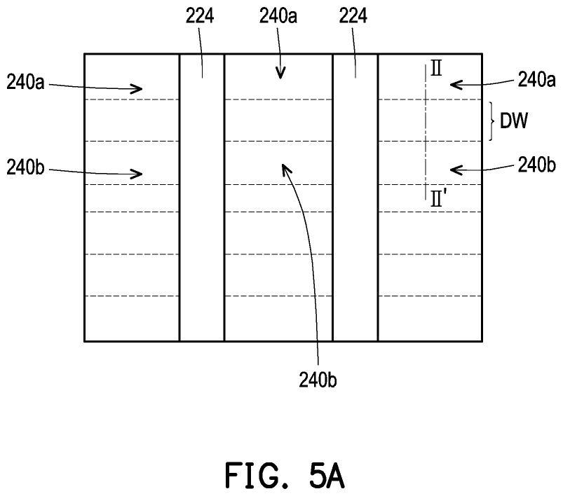

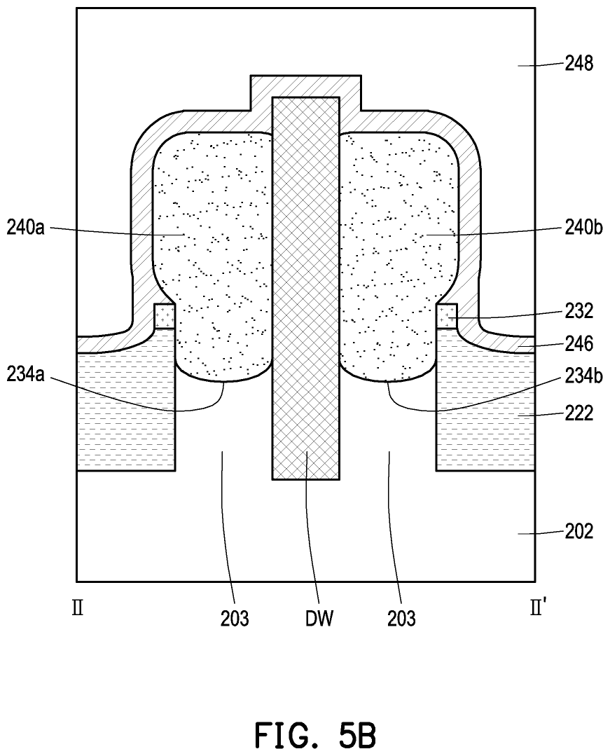

FIG. 5A illustrates a top view of stages of forming a semiconductor device, and FIG. 5B illustrates a cross-sectional view taken along lines II-IF of FIG. 5A. It is noted that in some embodiments, when performing the process of FIG. 5A and FIG. 5B, the channel members (or called channel regions) of the nanosheet stacks 212 is covered by the dummy gate stack 224 as shown in FIG. 4A and FIG. 4B. Referring to FIG. 5A, strained layers 240a, 240b are formed on the fins 203 respectively. In some embodiments, as shown in FIG. 4A, the dummy gate stack 224 covers portions (e.g., middle portions) of the nanosheet stacks 212, and reveals other portions of the nanosheet stacks 212. Then, a spacer 232 is formed to stand over and align to the edges of insulating regions 222. In some embodiments, the spacer 232 includes a dielectric material, such as silicon oxide, silicon nitride, SiON, SiC, SiCN, SiCON, or a combination thereof. Other materials such as a low-k material may be applicable. The low-k material has a dielectric constant less than 3.9, less than 3, less than 2.5, or even less. The spacer 232 may have a single-layer structure or a multi-layer structure. For example, the spacer 232 includes a silicon oxide material and a silicon nitride material on the silicon oxide material.

Then, the nanosheet stacks 212 are removed and the underlying fins 203 are recessed to form recesses 234a, 234b. In other words, the nanosheet stacks 212 are entirely removed and portions of the fins 203 are removed. The recesses 234a, 234b are referred to as “source/drain (S/D) recesses” in some examples. In some embodiments, the nanosheet stacks 212 are removed by an anisotropic etch process, an isotropic etch process, or a combination thereof. In some embodiments, top surfaces of the recesses 234a, 234b are lower than the top surfaces of the insulating regions 222. However, the disclosure is not limited thereto. In many embodiments, the method of forming the recesses 234a, 234b includes performing a suitable etch process, such as a dry etch process, a wet etch process, or an RIE process.

Then, the strained layers 240a, 240b are formed in the recesses 234a, 234b respectively. In some embodiments, the strained layers 240a, 240b are formed by an epitaxial growth process and are grown from the bottom of the recesses 234a, 234b. For example, when the substrate 202 includes silicon, the strained layers 240a, 240b are silicon-containing material. In alternative embodiments, before forming the strained layers 240a, 240b, liner layers (not shown) beneficial for forming the strained layers 240a, 240b in the recesses 234a, 234b are formed at the bottoms of the recesses 234a, 234b. In such embodiments, the liner layers improve a good interface for epitaxially growing the strained layers 240a, 240b.

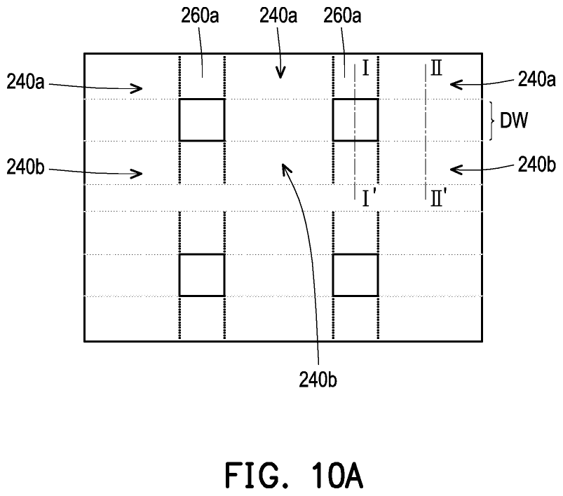

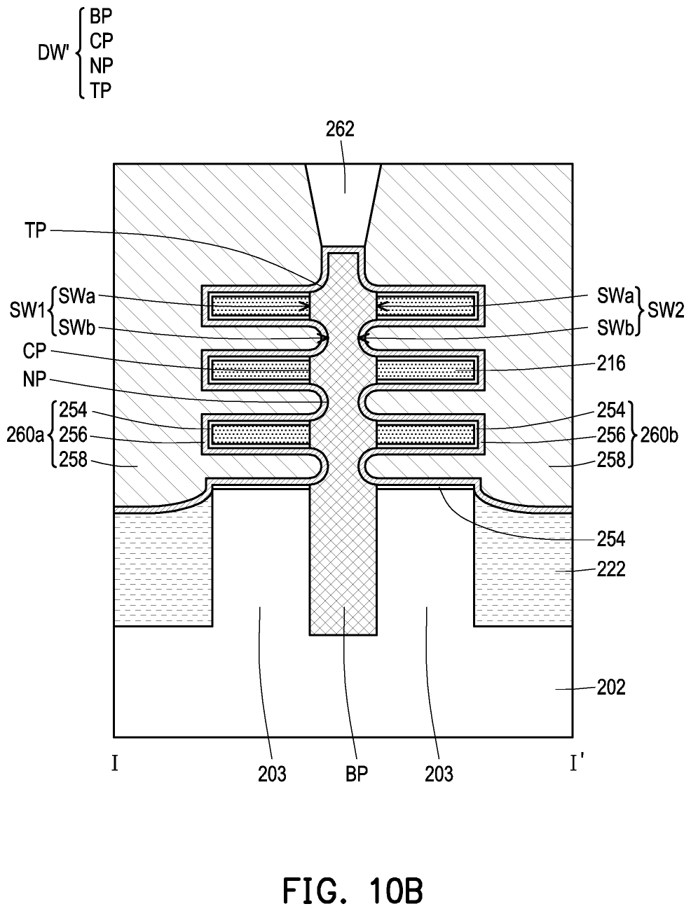

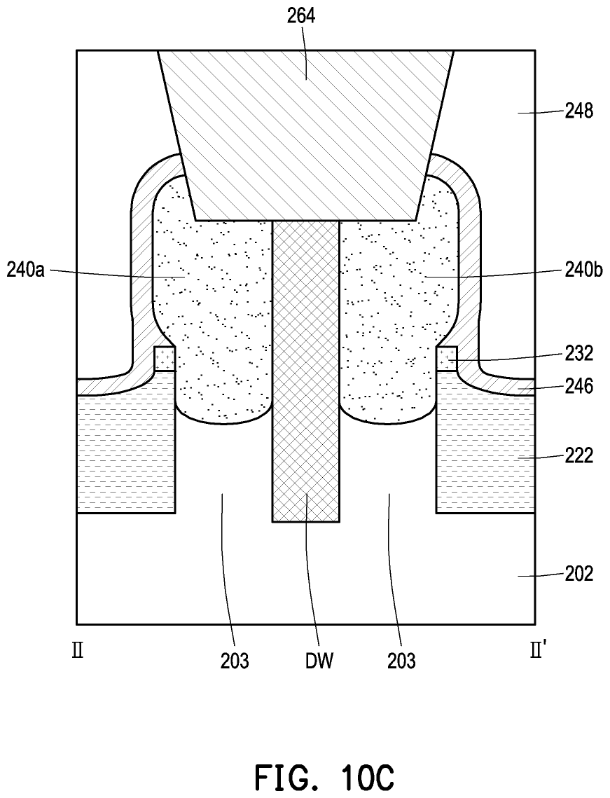

In some embodiments, the strained layers 240a, 240b are used to strain or stress the second nanosheets (which may be referred to as channel members) 216 and the fins 203. Herein, the strained layers may be referred to as “epitaxial layers”, “S/D regions” or “highly doped low resistance materials” in some examples. In some embodiments, the strained layers 240a, 240b include source regions and/or drain regions. The strained layers 240a, 240b are disposed on the fins 203 and abutted the nanosheet stacks 212, as shown in FIG. 10A to FIG. 10C. In some embodiments, the strained layers 240a, 240b extend beyond the top surfaces of the nanosheet stacks 212. However, the embodiments of the present disclosure are not limited thereto, in other embodiments, the top surfaces of the strained layers 240a, 240b are substantially flushed with the top surfaces of the nanosheet stacks 212.

In some embodiments, the strained layers 240a, 240b are doped with a conductive dopant. For example, the strained layer 240a is epitaxial-grown with an n-type dopant for straining an n-type device. That is, the strained layer 240a is doped with the n-type dopant to be the source or the drain of the n-type device. The n-type dopant includes arsenic and/or phosphorus, and the strained layer 240a may be epitaxial-grown by LPCVD process with in-situ doping. Similarly, the strained layer 240b may be epitaxial-grown with a p-type dopant for straining a p-type device. That is, the strained layer 240b is doped with the p-type dopant to be the source or the drain of the p-type device. The p-type dopant includes boron or BF 2, and the strained layer 240b may be epitaxial-grown by LPCVD process with in-situ doping. However, the disclosure is not limited thereto. In alternative embodiments, the strained layers 240a, 240b may have the same conductive type. For example, the strained layers 240a, 240b are both of n-type or p-type.

Then, a contact etch stop layer (CESL) 246 is formed over the exposed strained layers 240a and 240b and the dielectric wall DW. In some embodiments, the CESL 246 conformally covers the upper portions of the strained layers 240a and 240b, the upper portion of the dielectric wall DW, and the sidewall and the top surface of the spacers 232. The CESL 246 may include silicon nitride, silicon oxynitride, silicon nitride with oxygen (O) or carbon (C) elements, metal oxide such as Al₂O₃, the like, or a combination thereof, and may be formed by CVD, PVD, ALD, or a suitable process. In some embodiments, the CESL 246 fills gaps between the spacers 232 and the strained layers 240a, 240b. However, the disclosure is not limited thereto. In alternative embodiments, the gaps may remain between the formed CESL 246 and the strained layers 240a, 240b after the formation of the CESL 246.

Thereafter, an interlayer dielectric (ILD) layer 248 is formed over the CESL 246. In some embodiments, the ILD layer 248 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. In some other embodiments, the ILD layer 248 includes a low-k material. The low-k material has a dielectric constant less than 3.9, less than 3, less than 2.5, or even less. Examples of the low-k material include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), the like, or a combination thereof. In some embodiments, the ILD layer 248 has a single-layer structure or a multi-layer structure. In some embodiments, the ILD layer 248 is formed by FCVD, CVD, HDPCVD, SACVD, spin-on process, sputtering, or a suitable process.

In some embodiments, as shown in FIG. 5B, adjacent strained layers 240a, 240b are separated from each other by the dielectric wall DW therebetween. In other words, the strained layers 240a, 240b are disposed at opposite sides of the dielectric wall DW. For example, the strained layer 240a is disposed at a first side of the dielectric wall DW, and the strained layer 240b is disposed at a second side opposite to the first side of the dielectric wall DW. In some embodiments, as a result of the epitaxial-grown process used to form the strained layers 240a, 240b, the cross-sectional views of the strained layers 240a, 240b have a bulb-like shape, and portions of the sidewalls of the strained layers 240a, 240b are conformal to and in contact with the dielectric wall DW. In some embodiments, the dielectric wall DW has substantially vertical sidewalls, and thus the strained layers 240a, 240b respectively have a substantially vertical sidewall leaned on the dielectric wall DW. In alternative embodiments, the strained layers 240a, 240b have a diamond-like shape or a polygonal shape (e.g., a pentagonal shape, a hexagonal shape, etc.).

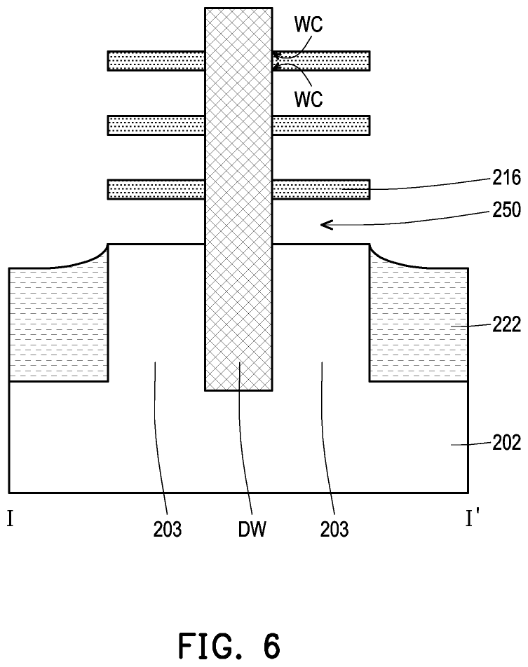

FIG. 6 to FIG. 9 illustrate cross-sectional views taken along lines I-I′ of FIG. 4A. Referring to FIG. 4B and FIG. 6, in some embodiments, after formation of the strained layers 240a, 240b and the dielectric wall DW as described above, the dummy gate stack 224 (including the dummy gate electrode layer 228 and the dummy gate dielectric layer 226) is removed, and channel members (or called channel regions) are defined for the semiconductor device. The ILD layer 248 and the CESL layer 246 protect the stained layers 240a, 240b as shown in FIG. 5B during the removal of the dummy gate stack 224. The dummy gate stack 224 may be removed using plasma dry etching and/or wet etching. When the dummy gate electrode layer 228 is polysilicon and the ILD layer 248 is silicon oxide, a wet etchant such as a TMAH solution may be used to selectively remove the dummy gate electrode layer. The dummy gate dielectric layer 226 is then removed using plasma dry etching and/or wet etching.

In some embodiments, an etch process is performed to remove the first nanosheets 214. In the case, the first nanosheets 214 may be completely removed to form gaps 250 between the second nanosheets 216, as shown in FIG. 6. Accordingly, the second nanosheets 216 are separated from each other by the gaps 250. In addition, the bottommost second nanosheet 216 may also be separated from the fin 203 by the gaps 250. As a result, the second nanosheets 216 are suspended. In some embodiments, the suspended second nanosheets 216 may be referred to as “channel members” or “channel regions”. As shown in FIG. 6, the second nanosheets 216 separated from each and vertically stacked are referred to as a “stack of semiconductor nanosheets” or “stack of semiconductor channels” in some examples.

In some embodiments, a height of the gaps 250 may be about 5 nm to 30 nm. In the present embodiment, the second nanosheets 216 include silicon, and the first nanosheets 214 include silicon germanium. The first nanosheets 214 may be selectively removed by oxidizing the first nanosheets 214 using a suitable oxidizer, such as ozone. Thereafter, the oxidized first nanosheets 214 may be selectively removed. In some embodiments, the etch process includes a dry etch process to selectively remove the first nanosheets 214, for example, by applying an HCl gas at a temperature of about 20° C. to about 300° C., or applying a gas mixture of CF₄, SF₆, and CHF₃. As shown in FIG. 6, after removal of the first nanosheets 214, the top surface of the dielectric wall DW is higher than the topmost second nanosheet 216.

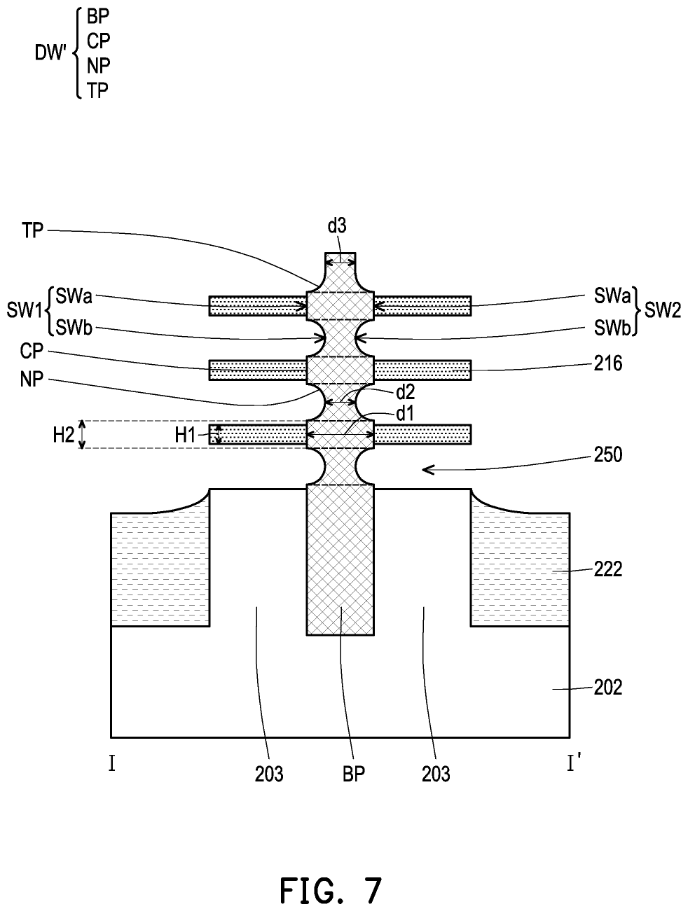

Referring to FIG. 7, an etch process such as an etch back process is performed on sidewalls of the dielectric wall DW. In some embodiments, the etch process uses a dry etch process or a suitable process. In some embodiments, during the etch process, the sidewalls of the dielectric wall DW′ not covered by the nanosheets 216 are partially removed (recessed), to narrow (shrink) down the width of portions of the dielectric wall DW′. For example, portions of the dielectric wall DW′ have a variable horizontal dimension (e.g., width) d2 while portions of the dielectric wall DW′ covered by the nanosheets 216 have the horizontal dimension (e.g., width) d1. In some embodiments, after partially removed, the dielectric wall DW′ has opposing jagged (e.g., wavy or omega shaped) sidewalls SW1, SW2. For example, the sidewalls SW1, SW2 has a plurality of first portions SWa and a plurality of second portions SWb alternately and vertically arranged. The first portions SWa are physically connected to the nanosheets 216 and substantially straight, and the second portions SWb are exposed and curved and/or concave, for example. The second portions SWb may respectively an arc having a radius of curvature. In some embodiments, the radius of curvature of the second portions SWb is substantially the same or similar. For example, the radius of curvature of the second portions SWb is in a range of 0.5 to 5 nm. The first portions SWa and the second portions SWb interposed therebetween together form a jagged (e.g., wavy or omega shaped) sidewall SW1, SW2, for example. In some embodiments, the first portions SWa are in direct contact with the nanosheets 216. In some embodiments, the dielectric wall DW′ has opposing jagged (e.g., wavy or omega shaped) sidewalls SW1, SW2. However, the disclosure is not limited thereto. In alternative embodiments (not shown), one of the opposing sidewalls is jagged (e.g., wavy or omega shaped), and the other of the opposing sidewalls is straight.

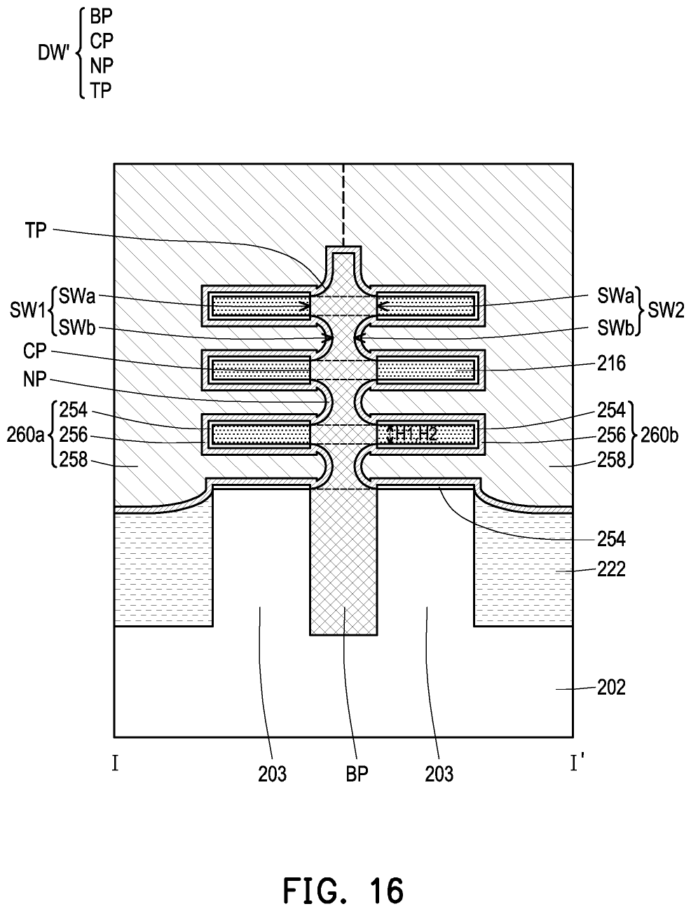

As shown in FIG. 7, the dielectric wall DW′ has at least one neck portion NP. In some embodiments, the dielectric wall DW′ has a plurality of connecting portions CP and a plurality of neck portions NP between a bottom portion BP and a top portion TP. The bottom portion BP is disposed in the substrate 202, and the connecting portions CP, the neck portions NP and the top portion TP protrude from the substrate 202, for example. In some embodiments, as shown in FIG. 7, the bottom portion BP is partially protruded from the substrate 202. However, the disclosure is not limited thereto. The bottom portion BP may be entirely embedded in the substrate 202. In some embodiments, the neck portions NP and the connecting portions CP are alternately stacked over the bottom portion BP, and the top portion TP is disposed on the neck portions NP and the connecting portions CP. The connecting portions CP are physically connected to the nanosheets 216 respectively. For example, first sides of the connecting portions CP are physically connected to the nanosheets 216 on one fin 203, and second sides of the connecting portions CP are physically connected to the nanosheets 216 on another fin 203. In some embodiments, a height H2 of the connecting portion CP is larger than a height H1 of a respective nanosheet 216 which is connected to the connecting portion CP. In other words, portions of sidewalls (e.g., first portions SWa) of the connecting portions CP are exposed. However, the disclosure is not limited thereto. In alternative embodiments, as shown in FIG. 16, a height H2 of the connecting portion CP is substantially the same as a height H1 of a respective nanosheet 216 which is connected to the connecting portion CP. The neck portion NP is disposed between the bottom portion BP and the connecting portion CP or between adjacent connecting portions CP, and the neck portion NP is disposed between the fin 203 and the nanosheet 216 or between adjacent nanosheets 216, for example. In some embodiments, the connecting portion CP has a constant horizontal dimension (e.g., width) d1 and the neck portion NP has a variable horizontal dimension (e.g., width) d2. The horizontal dimension d2 of the neck portion NP increases as the neck portion NP becomes closer to the connecting portion CP, for example. In some embodiments, a top surface of the top portion TP is higher than top surfaces of the nanosheets 216. The top portion TP has a variable horizontal dimension (e.g., width) d3, and the horizontal dimension d3 decreases as the top portion TP becomes far away from the connecting portion CP (or the substrate 202), for example. In some embodiments, the first portions SWa of the sidewalls SW1, SW2 are also referred to as sidewalls of the connecting portions CP and the bottom portion BP, and second portions SWb of the sidewalls SW1, SW2 are also referred to as sidewalls of the neck portions NP and the top portion TP.

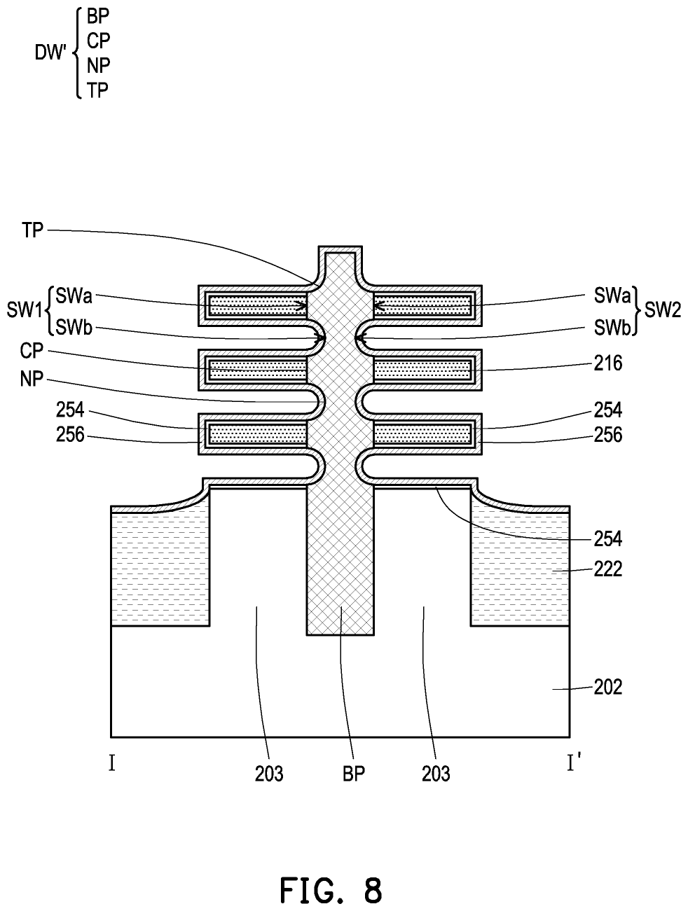

Referring to FIG. 8, a gate dielectric layer 256 is formed on the exposed surfaces of the nanosheets 216 and the dielectric wall DW′. In some embodiments, the gate dielectric layer 256 conformally covers the exposed surfaces of the nanosheets 216 and the dielectric wall DW′ and thus wraps around the nanosheets 216 in the channel regions. For example, the gate dielectric layer 256 is in direct contact with the exposed sidewalls SW1, SW2 (e.g., second portions SWb or sidewalls of the neck portions NP) of the dielectric wall DW′. In some embodiments, the gate dielectric layer 256 includes at least one dielectric material, such as a high-k material. Examples of the high-k material include metal oxide, such as HfO₂, HfSiO, HfSiON, HfTaO, HfSiO, HfZrO, zirconium oxide, aluminum oxide, titanium oxide, hafnium dioxide-alumina (HfO₂—Al₂O₃) alloy, the like, or combinations thereof. The high-k material has a dielectric constant less than 8, less than 15, less than 20, or even more. The gate dielectric layer 256 may be formed by CVD, ALD or a suitable method. In one embodiment, the gate dielectric layer 256 is formed by using a highly conformal deposition process, such as ALD in order to ensure the formation of a gate dielectric layer having a uniform thickness around each channel members. The thickness of the gate dielectric layer 256 is in a range from about 0.5 nm to about 3 nm in some embodiments.

In some embodiments, as shown in FIG. 8, an interfacial layer 254 is further formed between each channel members (e.g., nanosheet 216) and the gate dielectric layer 256 (e.g., high k material). For example, the interfacial layer 254 wraps each of the nanosheets 216 in the channel regions. In some embodiments, the interfacial layer 254 further covers portions of sidewalls (e.g., first portions SWa) of the connecting portions CP which are exposed by the nanosheets 216. For example, the first portion SWa is partially covered by the nanosheet 216b and partially covered by the interfacial layer 254. The interfacial layer 254 may be deposited or thermally grown respectively on the nanosheets 216 according to acceptable techniques, and made of, for example, silicon dioxide, a low-k dielectric material (e.g., a material having a dielectric constant lower than silicon dioxide), silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOₓC_{y}, Spin-On-Glass, Spin-On-Polymers, silicon carbon material, a compound thereof, a composite thereof, the like, or a combination thereof. The interfacial layer 254 may be further formed on the exposed top surface of the substrate 202 (e.g., fin 203), as shown in FIG. 8. The thickness of the interfacial layer 254 is in a range from about 0.7 nm to about 2.5 nm in some embodiments. In alternative embodiments, the interfacial layer and the high k material are collectively referred to as the gate dielectric layer. In some embodiments, as shown in FIG. 8, after formation of the interfacial layer 254 and the gate dielectric layer 256, the gaps 250 remain between the nanosheets 216. In alternative embodiments, the gaps 250 are entirely or partially filled by the gate dielectric layer 256.

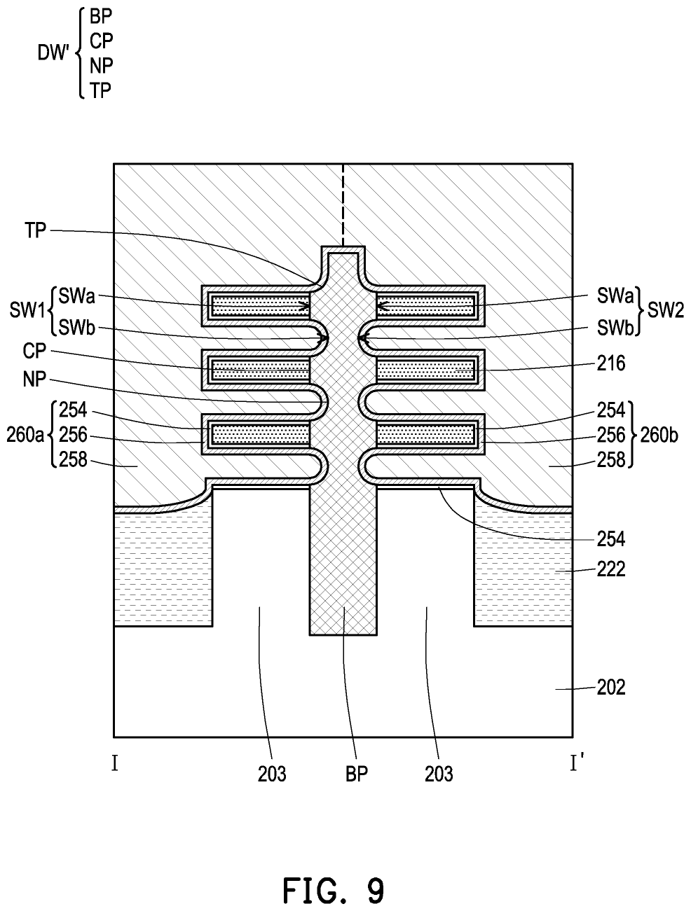

Referring to FIG. 9, a gate electrode 258 is formed on the gate dielectric layer 256 to surround each of the nanosheets 216. For example, the gate electrode 258 wraps around the nanosheets 216 in the channel regions with the gate dielectric layer 256 therebetween. In some embodiments, the gate electrode 258 completely fills the gaps 250. In some embodiments, the gate electrode 258 includes one or more conductive materials, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloy, a suitable material, or a combination thereof. The gate electrode 258 may be formed by CVD, ALD, electro-plating, or other suitable method. The gate dielectric layer 256 and the gate electrode 258 may also be deposited over the upper surfaces of the ILD layer 248 and the CESL layer 246. In such embodiments, the gate dielectric layer 256 and the gate electrode 258 formed over the ILD layer 248 and the CESL layer 246 are then planarized by using, for example, CMP, until the top surfaces of the ILD layer 248 and the CESL layer 246 are revealed. After the planarization operation, the gate electrode 258 is recessed and a cap insulating layer (not shown) is formed over the recessed gate electrode 258. The cap insulating layer includes one or more layers of a silicon nitride-based material, such as SiN. The cap insulating layer may be formed by depositing an insulating material followed by a planarization operation.

In other embodiments, one or more work function adjustment layers (not shown) are interposed between the gate dielectric layer 256 and the gate electrode 258. The work function adjustment layers are made of a conductive material, such as a single layer of TiN, TaN, TaAlC, TiC, TaC, Co, Al, TiAl, Hffi, TiSi, TaSi or TiAlC, or a multilayer of two or more of these materials. For the n-type device, one or more of TaN, TaAlC, TiN, TiC, Co, TiAl, Hifi, TiSi and TaSi is used as the work function adjustment layer, and for the p-type device, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-type device and the p-type device which may use different metal layers. In some embodiments, the gate electrode 258 and the gate dielectric layer 256 constitute a gate structure 260a, 260b. Specifically, as shown in FIG. 9, the gate structure 260a wraps the nanosheets 216 at a first side of the dielectric wall DW′, and the gate structure 260b wraps the nanosheets 216 at a second side opposite to the first side of the dielectric wall DW′. In some embodiments, corresponding to the profile of the dielectric wall DW′, the gate structure 260a, 260b has a jagged (e.g., wavy or omega shaped) inner sidewall. For example, the gate structure 260a, 260b is finger shaped (e.g., comb shaped), and the gate structure 260a, 260b has protrusions extending into the dielectric wall DW′.

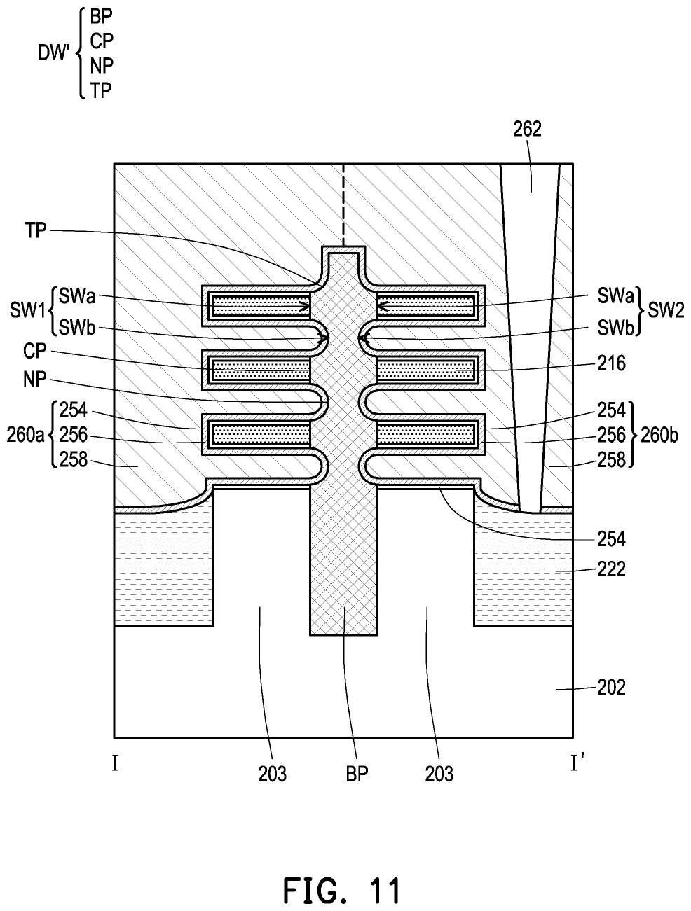

FIG. 10A to FIG. 10C illustrate varying views of stages of forming a semiconductor device. FIG. 10A illustrates a top view of a stage of forming a semiconductor device. FIG. 10B illustrates a cross-sectional view taken along a line I-I′ of FIG. 10A. FIG. 10C illustrates a cross-sectional view taken along a line II-IF of FIG. 10A. Referring to FIG. 10A and FIG. 10B, at a specific location, a cut gate structure 262 is formed between the gate structures 260a, 260b to separate the adjacent gate structures 260a, 260b. The material of the cut gate structures 262 may include silicon oxide, silicon nitride, silicon oxynitride, a spin-on dielectric material, or a low-k material. The cut gate structures 262 are referred to as “isolation strips”, “shallow trench isolation (STI) regions” or “deep trench isolation (DTI) regions” in some examples. The cut gate structure 262 may be formed at any suitable position. For example, as shown in FIG. 11, the cut gate structure 262 is disposed at another location, to separate the adjacent gate structures 260a, 260b. In such embodiments, the cut gate structure 262 includes a continuously extending vertical segment parallel to the dielectric wall DW′. In some embodiments, as shown in FIG. 10B, the gate dielectric layer 256 is disposed between the dielectric wall DW′ and the cut gate structure 262. However, the disclosure is not limited thereto. In alternative embodiments, the cut gate structure 262 is in direct contact with the dielectric wall DW′ without the gate dielectric layer 256 therebetween. In such embodiments, the gate dielectric layer 256 on the top of the dielectric wall DW′ and the top of the dielectric wall DW′ may be partially removed.

In some embodiments, as shown in FIG. 10C, a contact 264 is formed in the ILD layer 248 for the connection of the strained layers 240a, 240b. In some embodiments, the contact 264 is formed by penetrating the ILD layer 248 and the CESL 246, to be in direct contact with the strained layers 240a, 240b. In some embodiments, the contact 264 is in form of a line crossing the dielectric wall DW therebelow, and thus connects the strained layers 240a, 240b. In alternative embodiments, the contact 264 is in form of a via on the strained layer 240a, 240b respectively. In some embodiments, the contact 264 is in direct contact with the top surfaces of the dielectric wall DW and the stained layers 240a, 240b. In alternative embodiments, an interlayer dielectric (ILD) layer (not shown) is further formed over the ILD layer 248 and the CESL 246, and the contact 264 penetrates the ILD layer, the ILD layer 248 and the CESL 246.

Upon the formation of the gate structures 260a, 260b, a semiconductor device of the embodiment is thus accomplished. In some embodiments, the semiconductor device is a forksheet device. Due to the configuration of the dielectric wall DW′, the semiconductor device may be also referred to as an omega forksheet device. In alternative embodiments, weak corner turn on effect may be observed at locations WC between the nanosheet 216 and the dielectric wall DW as shown in FIG. 6 since the gate dielectric layer and the gate electrode to be formed are not easily to fill therein. This may cause on-current loss and a device degradation. However, in some embodiments, the sidewall of the dielectric wall is further etched to have a configuration such that the gate dielectric layer and the gate electrode may surround the locations WC. Accordingly, the effective channel width is increased and the weak corner turn-on effect is prevented or mitigated, for example. Thus, the performance of the semiconductor device may be improved.

The above embodiments of the configuration of the dielectric wall DW′ are provided for illustration purposes, and are not construed as limiting the present disclosure. The configuration in cross-section views of the dielectric wall DW′ may be modified upon the customer requirements. Various configurations in cross-section views of the dielectric walls DW′ are described in details below.

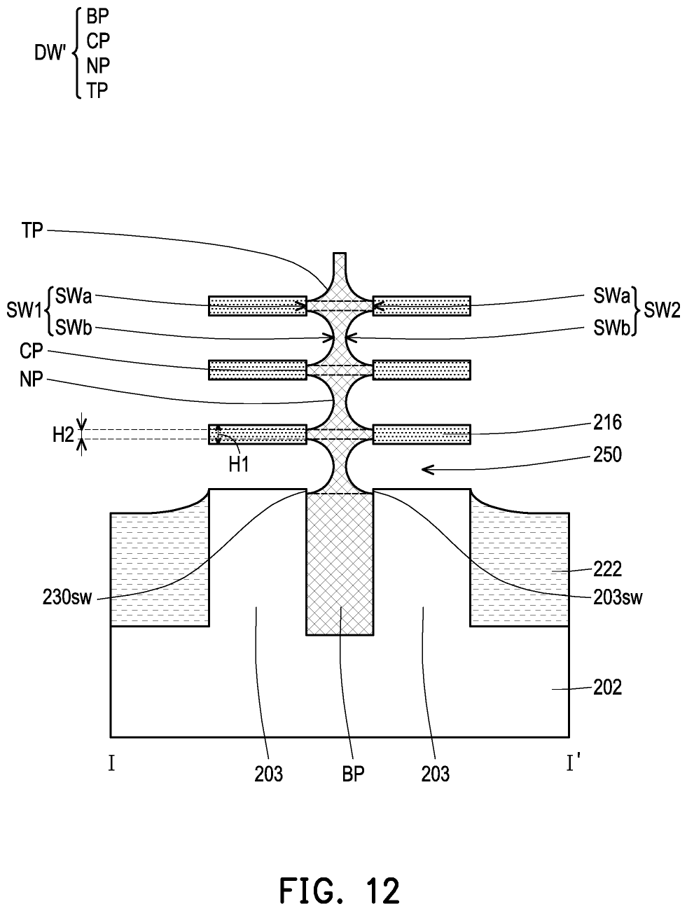

FIG. 12 to FIG. 15 illustrate varying views of a method of forming a semiconductor device in accordance with some embodiments. The processes of FIG. 12 to FIG. 15 are similar to the processes of FIG. 7 to FIG. 10B respectively, and the different between them lies in that the height H2 of the connecting portion CP is smaller than the height H1 of the nanosheet 216. It is noted that the material and forming method of elements having the same reference numerals as the previous embodiment may be substantially the same as those of the previous embodiments, so the detailed descriptions thereof are omitted herein.

Referring to FIG. 6 and FIG. 12, an etch process such as an etch back process is performed on the dielectric wall DW, to form the dielectric wall DW′. The dielectric wall DW′ has an omega-shaped sidewall SW1, SW2. In some embodiments, the height H2 of the connecting portion CP is smaller than the height H1 of the nanosheet 216. Thus, the sidewall of the nanosheet 216 (i.e., sidewall connected to the connecting portion CP) is partially exposed by the connecting portion CP. In some embodiments, a radius of curvature of the second portion SWb is larger than that of FIG. 7. In some embodiments, as shown in FIG. 12, the bottom portion BT is entirely disposed in the substrate 202, and the neck portion NP directly connected to the bottom portion BT is partially disposed in the substrate 202. As a result, a sidewall 203sw of the fin 203 (i.e., substrate 202) is exposed by the dielectric wall DW′, for example.

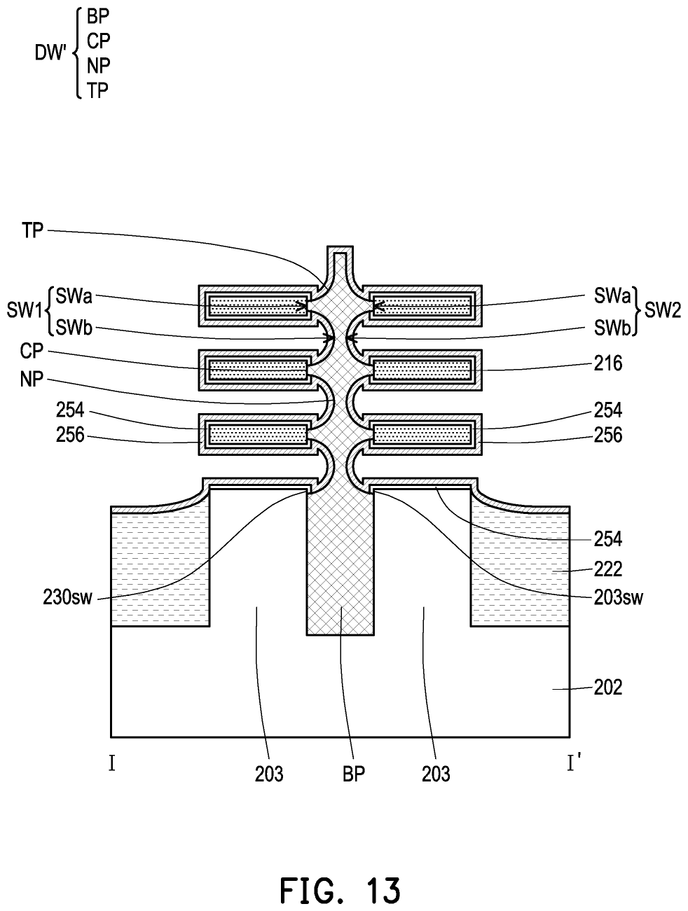

Referring to FIG. 13, an interfacial layer 254 is formed on the exposed surfaces of the nanosheets 216, and a gate dielectric layer 256 is formed on the exposed surfaces of the interfacial layer 254 and the dielectric wall DW′. In some embodiments, the interfacial layer 254 is further formed on the sidewall of the nanosheets 216 connected to and exposed by the connecting portion CP. For example, the nanosheet 216 is entirely surrounded by the interfacial layer 254 except the portion directly connected to the connecting portion CP. The gate dielectric layer 256 conforms on the interfacial layer 254 on the nanosheets 216 and the dielectric wall DW′, for example. In some embodiments, the interfacial layer 254 not only covers the top surface of the fin 203 but also covers the sidewall 203sw of the fin 203 exposed by the dielectric wall DW′, as shown in FIG. 13. The gate dielectric layer 256 may be also covers the sidewall 203sw of the fin 203.

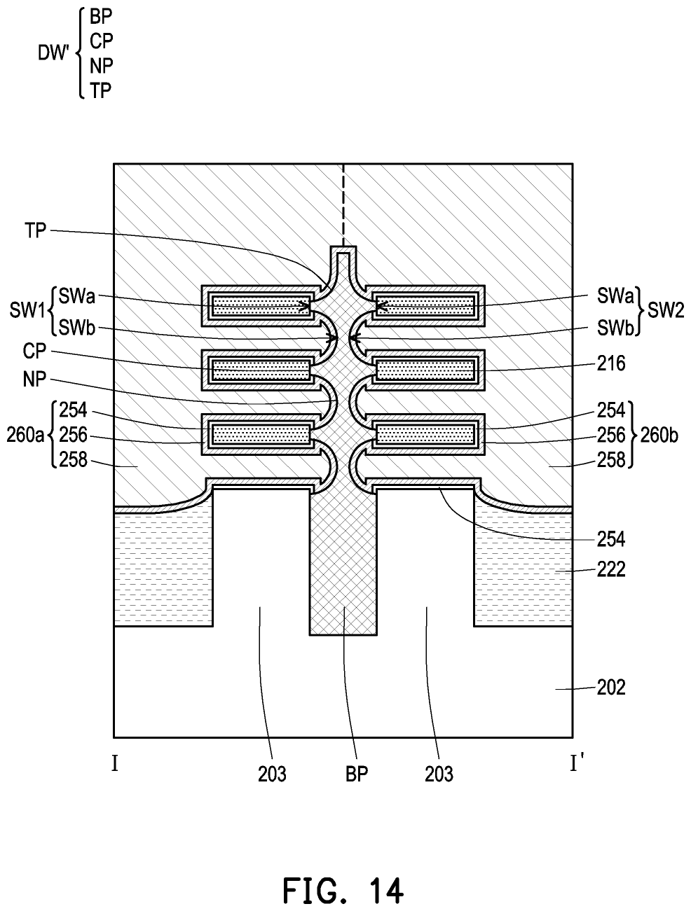

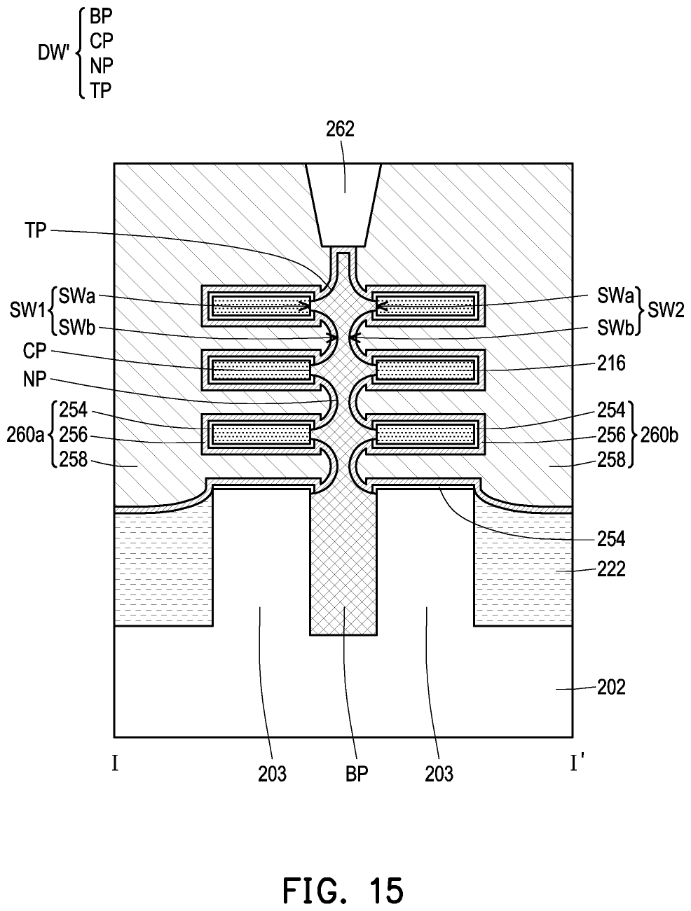

Referring to FIG. 14, a gate electrode 258 is formed on the gate dielectric layer 256 to surround each of the nanosheets 216, to form gate structures 260a, 260b. For example, the gate electrode 258 wraps around the nanosheets 216 in the channel regions with the gate dielectric layer 256 therebetween. Then, as shown in FIG. 15, at a specific location, a cut gate structure 262 may be formed between the gate structures 260a, 260b to separate the adjacent gate structures 260a, 260b.

In some embodiments, since the sidewall of the nanosheet 216 connected to the connecting portion CP is partially exposed, the gate electrode 258 is further inserted into the gaps (e.g., recesses) between the dielectric wall DW′ and the nanosheets 216 and between the dielectric wall DW′ and the fin 203. Accordingly, the nanosheets 216 are surrounded by the gate dielectric layer 256 and the gate electrode 258 with a larger area, for example. Thus, the effective channel width is increased and the weak corner turn-on effect is prevented or mitigated. Accordingly, the performance of the semiconductor device is improved.

In above embodiments, the height H2 of the connecting portion CP is different from (larger than or smaller than) the height H1 of the nanosheet 216. However, the disclosure is not limited thereto. In alternative embodiments, as shown in FIG. 16, the height H2 of the connecting portion CP is substantially the same as the height H1 of the nanosheet 216. In such embodiments, as shown in FIG. 16, a top surface of the bottom portion BP of the dielectric wall DW′ is substantially coplanar with a top surface of the fin 203 (e.g., the substrate 202).

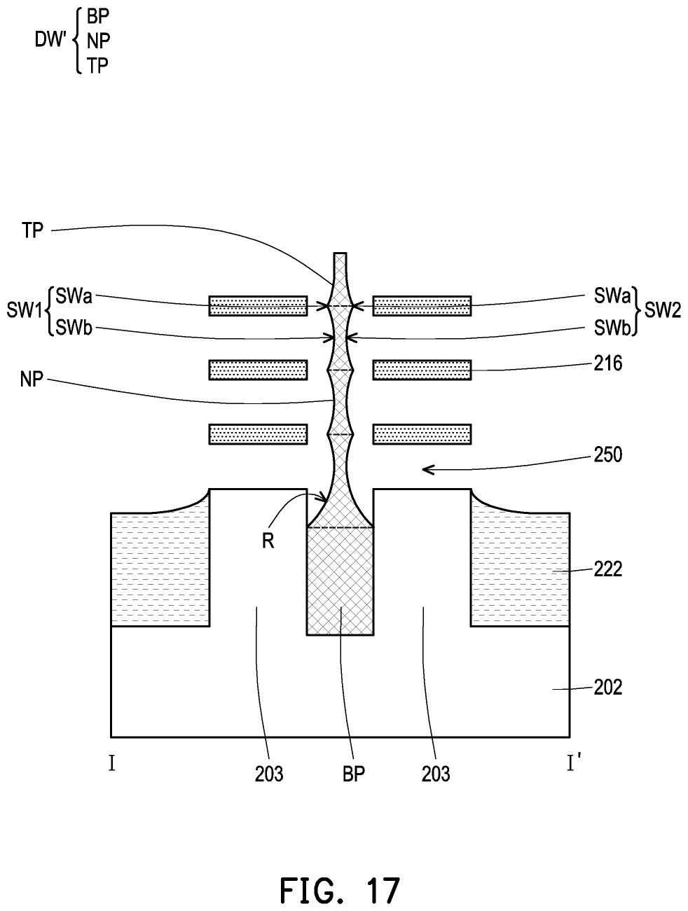

FIG. 17 to FIG. 20 illustrate varying views of a method of forming a semiconductor device in accordance with some embodiments. The processes of FIG. 17 to FIG. 20 are similar to the processes of FIG. 7 to FIG. 10B respectively, and the different between them lies in that the dielectric wall DW′ is configured to be separated from the nanosheets 216. It is noted that the material and forming method of elements having the same reference numerals as the previous embodiment may be substantially the same as those of the previous embodiments, so the detailed descriptions thereof are omitted herein.

Referring to FIG. 6 and FIG. 17, an etch process such as an etch back process is performed on the dielectric wall DW, to form the dielectric wall DW′. From a cross-sectional view as FIG. 17, the dielectric wall DW′ is physically separated from the nanosheets 216 and has a wavy sidewall. For example, the dielectric wall DW′ has a plurality of neck portions NP between the bottom portion BP and the top portions TP, and the neck portions NP are separated from and disposed between the adjacent nanosheets 216. The bottom portion BP may be embedded in the substrate 202 (e.g., between the fins 203) and have a top surface lower than a top surface of the substrate 202 (e.g., fin 203). As a result, a recess R is formed between the dielectric wall DW′ and the fin 203, for example. In some embodiments, a width of the neck portions NP and the top portion TP is smaller than a width of the bottom portion BP. In some embodiments, a radius of curvature of the second portion SWb is larger than that of FIG. 7 and FIG. 12 due to an increased removal amount of the dielectric wall DW′. FIG. 7, FIG. 12 may be intermediate structure during the etch process for forming the dielectric wall DW′ of FIG. 17. In other words, FIG. 7, FIG. 12 and FIG. 17 are sequentially formed during the etch process, for example.

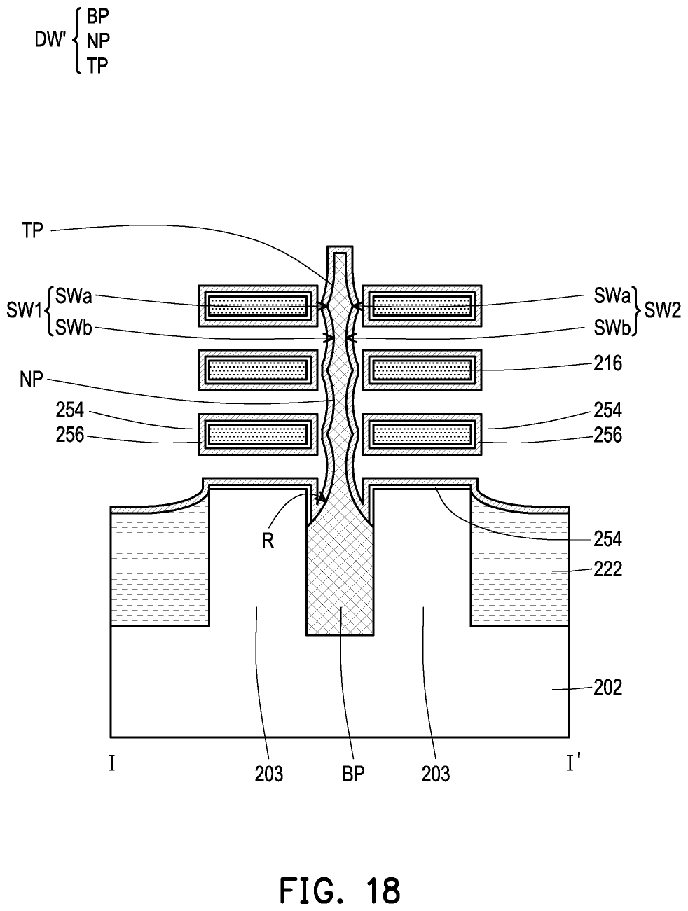

Referring to FIG. 18, an interfacial layer 254 is formed on the exposed surfaces of the nanosheets 216, and a gate dielectric layer 256 is formed on the exposed surfaces of the interfacial layer 254 and the dielectric wall DW′. In some embodiments, the nanosheets 216 are entirely surrounded by the interfacial layer 254 respectively, and the sidewalls SW1, SW2 and the top surface of the dielectric wall DW′ are entirely covered by the interfacial layer 254. The gate dielectric layer 256 conforms on the interfacial layer 254 surrounding the nanosheets 216 and the dielectric wall DW′, for example. In some embodiments, the interfacial layer 254 not only covers the top surface of the fin 203 but also covers the sidewall 203sw of the fin 203 exposed by the recess R. For example, the interfacial layer 254 and the gate dielectric layer 256 are formed on the sidewall 203sw of the fin 203 to partially fill the recess R. As shown in FIG. 18, the interfacial layer 254 and the gate dielectric layer 256 are inserted between the fin 203 and the dielectric wall DW′. From a cross-sectional view as shown in FIG. 18, the gate dielectric layer 256 on the nanosheet 216 is physically separated from the gate dielectric layer 256 on the dielectric wall DW′, for example. However, the disclosure is not limited thereto. In alternative embodiments (not shown), the gate dielectric layer 256 on the nanosheet 216 is merged with the gate dielectric layer 256 on the dielectric wall DW′ depended on the distance between the dielectric wall DW′ and the nanosheet 216 and/or the thickness of the interfacial layer 254 and/or the gate dielectric layer 256. In such embodiments, the gate dielectric layer 256 physically connects the nanosheet 216 and the dielectric wall DW′.

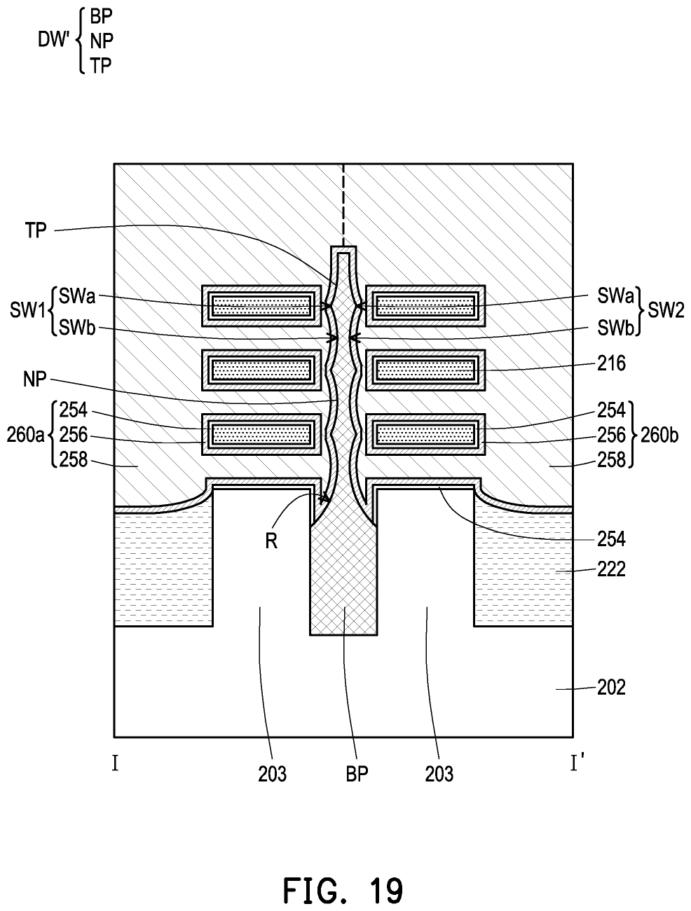

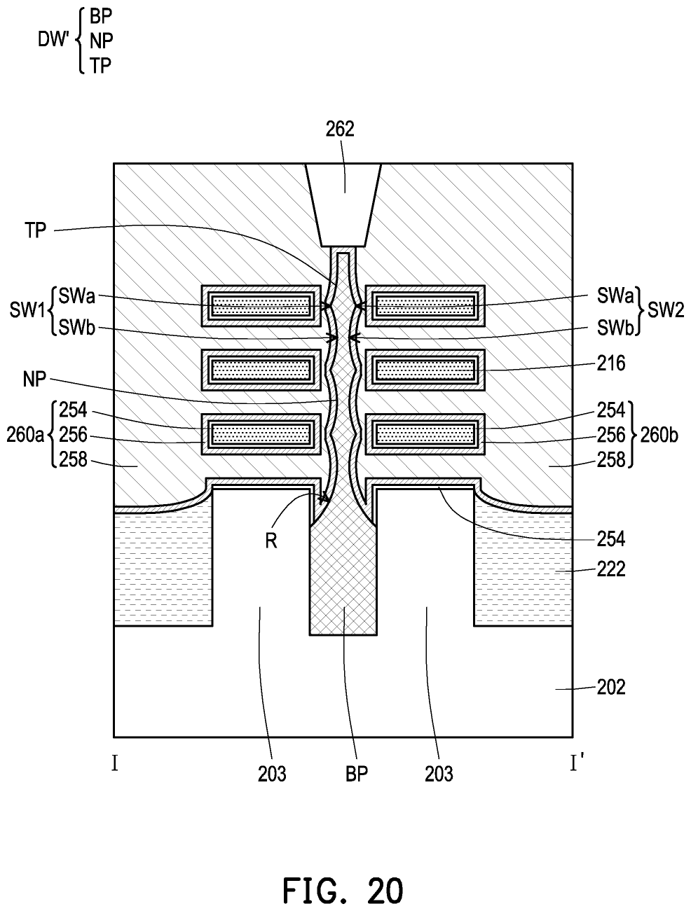

Referring to FIG. 19, a gate electrode 258 is formed on the gate dielectric layer 256 to surround each of the nanosheets 216, to form gate structures 260a, 260b. For example, the gate electrode 258 wraps around the nanosheets 216 in the channel regions with the gate dielectric layer 256 therebetween. In some embodiments, in the cross-sectional view, the nanosheets 216 are entirely surrounded (wrapped) by the gate structures 260a, 260b respectively. The gate electrode 258 is, for example, inserted between the gate dielectric layer 256 on the nanosheet 216 and the gate dielectric layer 256 on the dielectric wall DW. In such embodiments, the semiconductor device is also referred to as GAA forksheet device. In some embodiments, as shown in FIG. 18 and FIG. 19, if the recess R is not filled up by the interfacial layer 254 and the gate dielectric layer 256, the gate electrode 258 is further inserted between the dielectric wall DW′ and the fin 203 to fill up the recess R. Then, as shown in FIG. 20, at a specific location, a cut gate structure 262 may be formed between the gate structures 260a, 260b to separate the adjacent gate structures 260a, 260b.

In some embodiments, since the nanosheets 216 are not connected to the dielectric wall DW′, the gate electrode 258 is further inserted between the dielectric wall DW′ and the nanosheets 216. Accordingly, the nanosheets 216 are entirely surrounded by the gate dielectric layer 256 and the gate electrode 258 with a larger area, for example. Thus, the effective channel width is increased and the weak corner turn-on effect is prevented or mitigated. Accordingly, the performance of the semiconductor device is improved.

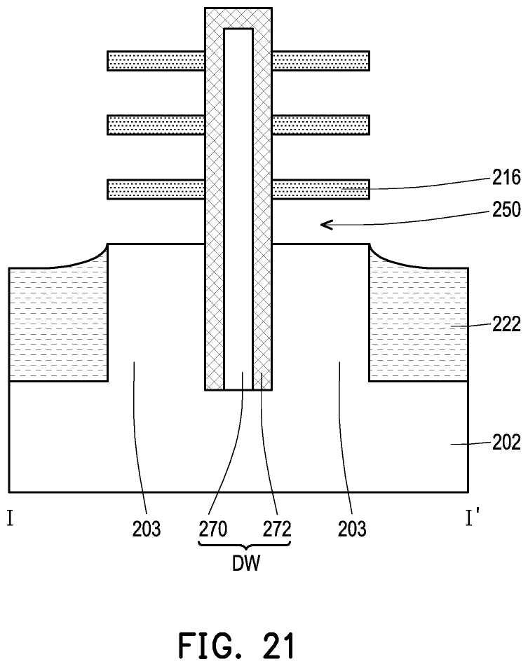

FIG. 21 to FIG. 26 illustrate varying views of a method of forming a semiconductor device in accordance with some embodiments. The processes of FIG. 21 to FIG. 26 are similar to the processes of FIG. 5B, FIG. 6 and FIG. 12 to FIG. 15 respectively, and the different between them lies in that the dielectric wall DW, DW′ has a multi-layer structure. It is noted that the material and forming method of elements having the same reference numerals as the previous embodiment may be substantially the same as those of the previous embodiments, so the detailed descriptions thereof are omitted herein.

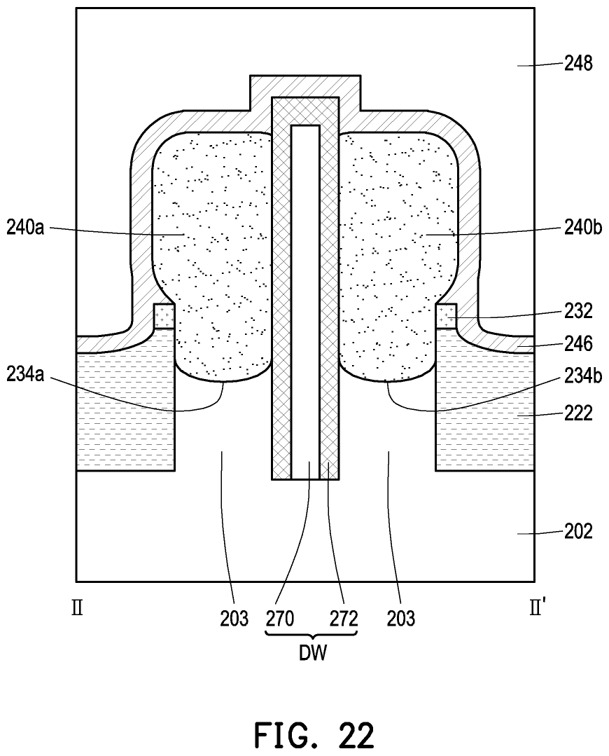

Referring to FIG. 21 and FIG. 22, in some embodiments, the dielectric wall DW has a plurality of dielectric layers 270, 272. In some embodiments, the multi-layered dielectric wall DW is disposed between the nanosheets 216 over the fins 203 as shown in FIG. 21, and the multi-layered dielectric wall DW is disposed between the adjacent strained layers 240a, 240b to provide the isolation therebetween as shown in FIG. 22. The dielectric layer 270 is also referred to as an inner dielectric layer, and the dielectric layer 270 is covered by the dielectric layer 272. For example, a top surface and sidewalls of the dielectric layer 270 are covered by the dielectric layer 272. A bottom surface of the dielectric layer 270 may be substantially coplanar with a bottom surface of the dielectric layer 272. The bottom surfaces of the dielectric layer 270 and the dielectric layer 272 are in direct contact with the substrate 202, for example. The dielectric layer 270, 272 may have respectively a single-layer structure or a multi-layer structure. The dielectric layer 270 and the dielectric layer 272 have materials with different etching selectivity, and thus the dielectric layer 270 may serve as an etch stop layer during the etch process of the dielectric wall DW. For example, an etch rate of the dielectric layer 270 is lower than an etch rate of the dielectric layer 272. The dielectric layer 270 and the dielectric layer 272 may respectively include a dielectric material, such as silicon oxide, silicon nitride, SiON, SiC, SiCN, SiCO, SiCON, a high-k material, the like, or a combination thereof. The high-k material includes metal oxide, such as HfO₂, HfSiO, HfSiON, HfTaO, HfSiO, HfZrO, zirconium oxide, aluminum oxide (Al₂O₃ or AlSiOₓ), titanium oxide, hafnium dioxide-alumina (HfO₂—Al₂O₃) alloy, the like, or combinations thereof. The high-k material has a dielectric constant less than 8, less than 15, less than 20, or even more. Other materials such as a low-k material may be applicable, which mitigates electrical coupling between n-type and p-type strained layers. The low-k material has a dielectric constant less than 3.9, less than 3, less than 2.5, or even less. Other materials such as a low-k material may be applicable. The low-k material has a dielectric constant less than 3.9, less than 3, less than 2.5, or even less. The dielectric layer 270 may have a thickness in a range of 1 nm to 10 nm, and the dielectric layer 272 may have a thickness in a range of 5 to 40 nm.

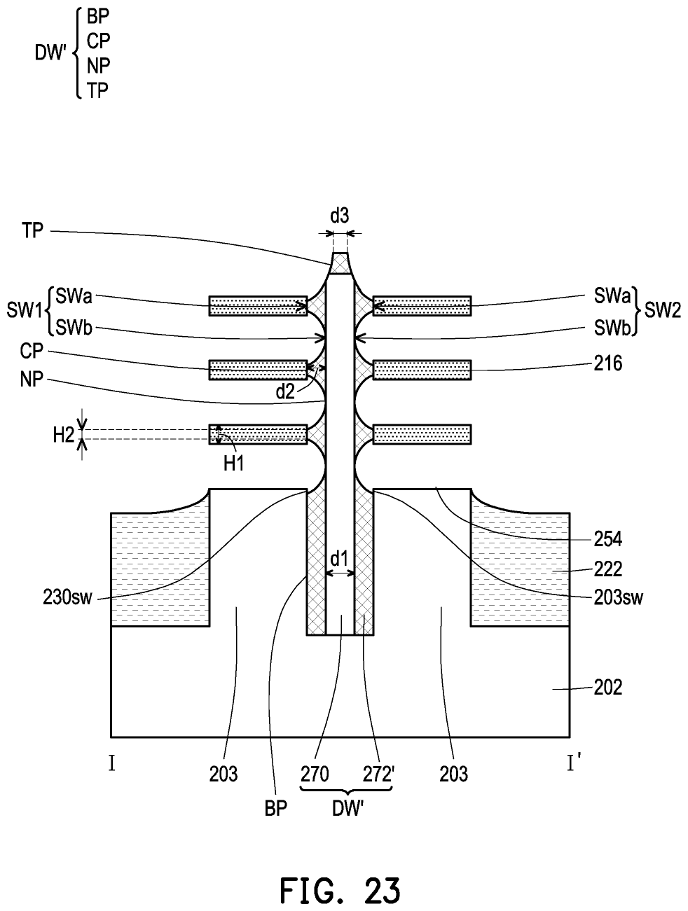

Referring to FIG. 23, an etch process such as an etch back process is performed on the dielectric wall DW, to form the dielectric wall DW′. During the etch process, the dielectric layer 272 is partially removed to form the dielectric layer 272′ while the dielectric layer 270 serves as an etch stop layer and thus remains intact. In some embodiments, the etch process is performed until the dielectric layer 270 is exposed. For example, a radius of curvature of the second portion SWb of the sidewall SW1, SW2 is defined by the dielectric layer 270. In some embodiments, after the etch process, the dielectric layer 272′ forms a top portion TP on a top surface of the dielectric layer 270 and a plurality of connecting portions CP and a bottom portion BP on sidewalls of the dielectric layer 270. The top portion TP is mountain-shaped with a flat top and curved sidewalls, for example. The connecting portions CP are separated from each other, for example. In some embodiments, portions of the dielectric layer 270 are exposed by the dielectric layer 272′, and the exposed portions of the dielectric layer 270 are also referred to as neck portions NP. For example, the exposed portions of the dielectric layer 270 are disposed between the connecting portions CP respectively. In alternative embodiments (not shown), the etch process is finished before the dielectric layer 270 is exposed, and thus the dielectric layer 270 is entirely covered by the dielectric layer 272′ without being exposed. In such embodiments, the neck portion NP is formed by both the dielectric layer 270 and the dielectric layer 272′ covered thereon between the connecting portions CP. In some embodiments, the connecting portions CP on opposite sides of the dielectric layer 270 together have a diamond shape. The dielectric wall DW′ has an omega-shaped sidewall SW1, SW2. In some embodiments, the connecting portions CP and the bottom portion BP are also referred to as side portions or dielectric portions since they are disposed on the sidewalls of the dielectric layer 270, and the dielectric layer 270 is also referred to a dielectric pillar. In some embodiments, the height H2 of the connecting portion CP is smaller than the height H1 of the nanosheet 216. Thus, the sidewall of the nanosheet 216 (i.e., sidewall connected to the connecting portion CP) is partially exposed by the connecting portion CP. The dielectric layer 270 has a substantially constant horizontal dimension (e.g., width) d1 since the dielectric layer 270 is not etched, for example. The connecting portion CP have a variable horizontal dimension (e.g., width) d2, and the horizontal dimension d2 decreases as the connecting portions CP becomes away from the nanosheet 216. The top portion TP has a variable horizontal dimension (e.g., width) d3, and the horizontal dimension d3 decreases as the top portion TP becomes far away from the dielectric layer 270.

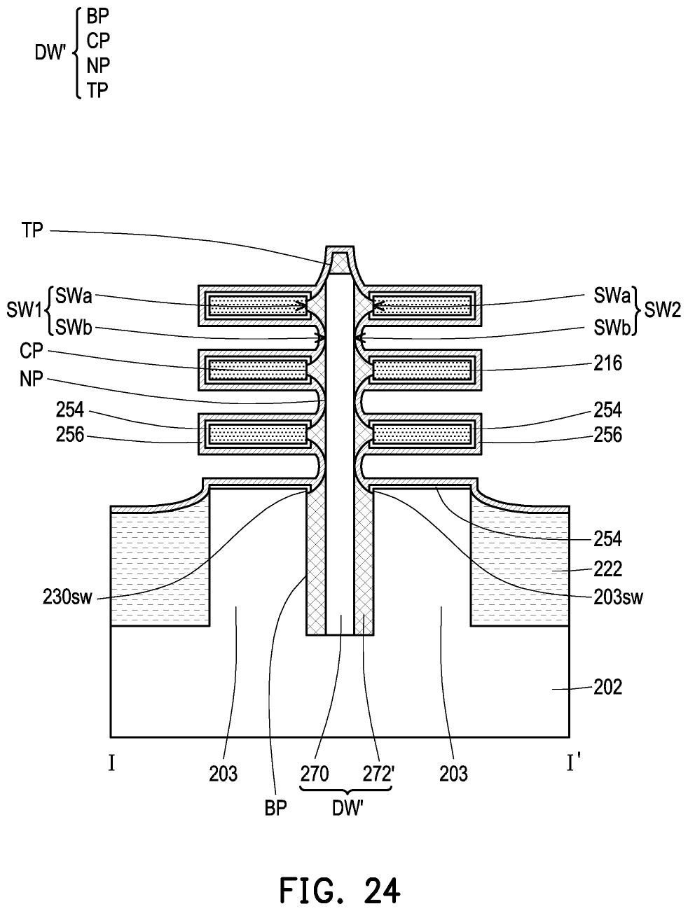

Referring to FIG. 24, an interfacial layer 254 is formed on the exposed surfaces of the nanosheets 216, and a gate dielectric layer 256 is formed on the exposed surfaces of the interfacial layer 254 and the dielectric wall DW′. In some embodiments, the gate dielectric layer 256 conforms on the interfacial layer 254 on the nanosheets 216 and the dielectric wall DW′. For example, the gate dielectric layer 256 is conformally formed on exposed surfaces of the dielectric layer 270 and the dielectric layer 272′. In some embodiments, the gate dielectric layer 256 is in direct contact with both the dielectric layer 270 and the dielectric layer 272′. In alternative embodiments in which the dielectric layer 270 is entirely covered by the dielectric layer 272′, the gate dielectric layer 256 is not in direct contact with the dielectric layer 270.

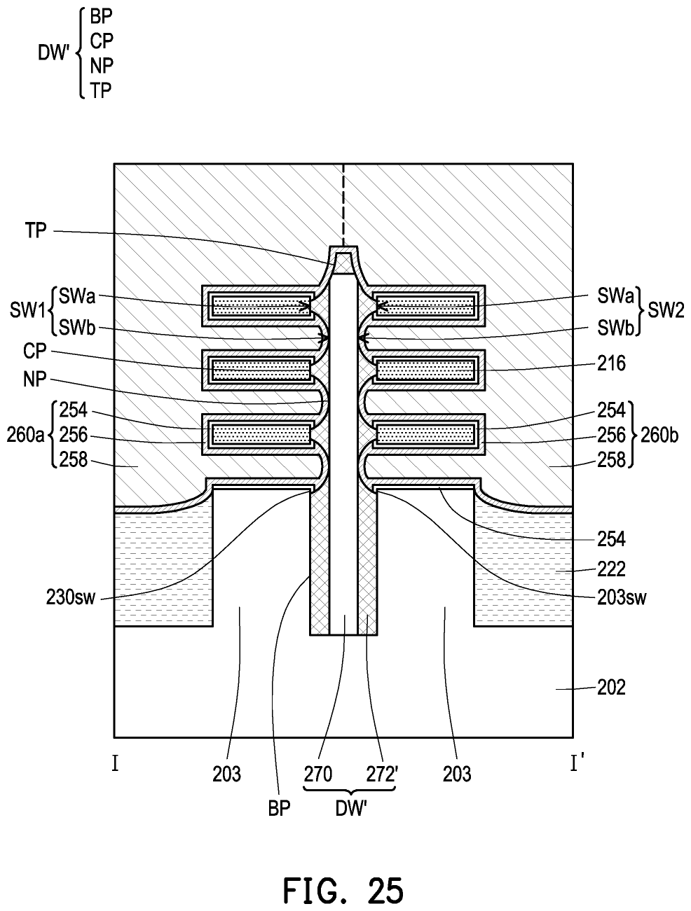

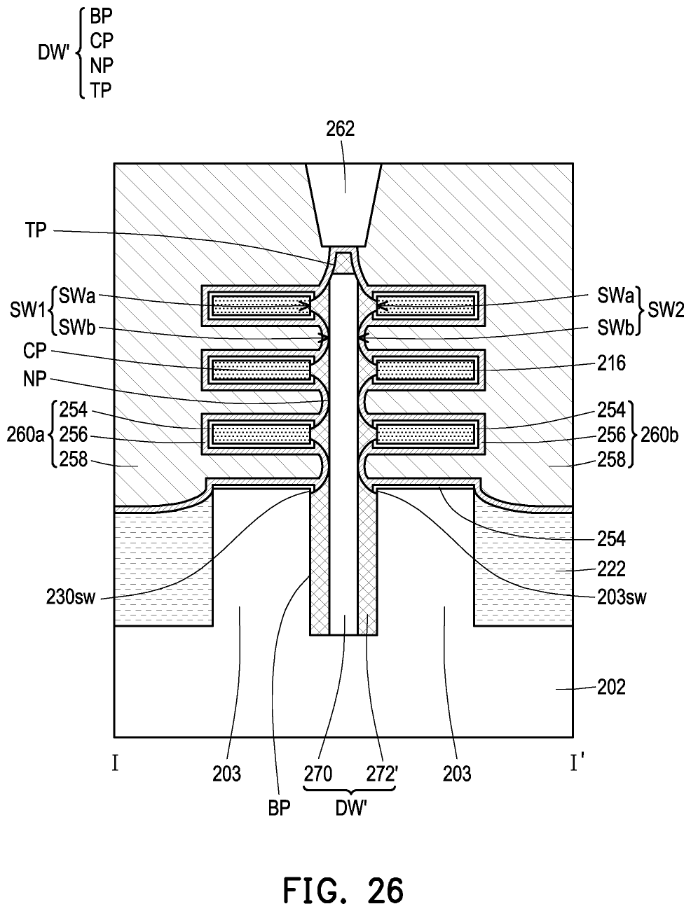

Referring to FIG. 25, a gate electrode 258 is formed on the gate dielectric layer 256 to surround each of the nanosheets 216, to form gate structures 260a, 260b. For example, the gate electrode 258 wraps around the nanosheets 216 in the channel regions with the gate dielectric layer 256 therebetween. Then, as shown in FIG. 26, at a specific location, a cut gate structure 262 may be formed between the gate structures 260a, 260b to separate the adjacent gate structures 260a, 260b.

In some embodiments, the dielectric wall has multi-layered structure, and the inner dielectric layer serves as an etch stop layer during the etch process of the dielectric wall. Thus, the dielectric wall is prevented from being over-etched. Accordingly, the dielectric wall may have robust structure to provide isolation and support. In addition, since the dielectric wall has wavy sidewalls, the gate electrode may be further inserted into the gaps between the dielectric wall and the nanosheets. Accordingly, the nanosheets may be surrounded by the gate dielectric layer and the gate electrode with a larger area, and the effective channel width is increased. Thus, the weak corner turn-on effect is prevented or mitigated, and the performance of the semiconductor device is improved.

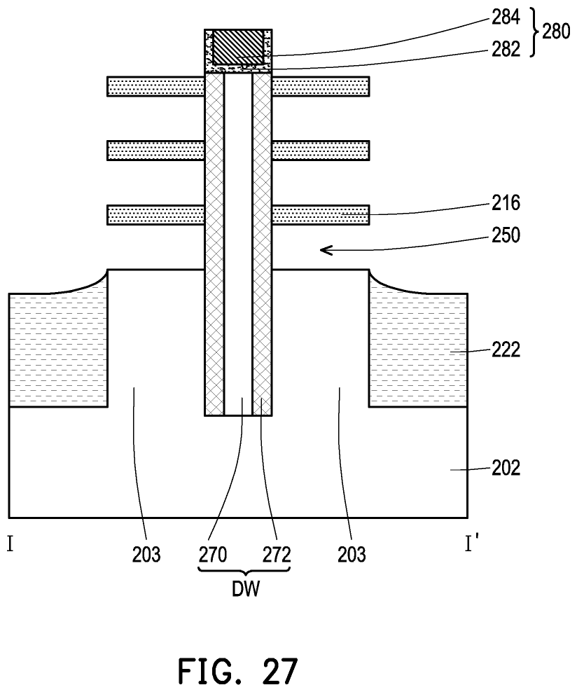

FIG. 27 to FIG. 31 illustrate varying views of a method of forming a semiconductor device in accordance with some embodiments. The processes of FIG. 27 to FIG. 30 are similar to the processes of FIG. 21 and FIG. 23 to FIG. 26 respectively, and the different between them lies in that the dielectric wall DW, DW′ further includes a cap layer 280 thereon. It is noted that the material and forming method of elements having the same reference numerals as the previous embodiment may be substantially the same as those of the previous embodiments, so the detailed descriptions thereof are omitted herein.

Referring to FIG. 27, in some embodiments, the dielectric wall DW further includes a cap layer 280 thereon. The cap layer 280 has a single-layer structure or a multi-layer structure. For example, the cap layer 280 includes a dielectric layer 282 and a dielectric layer 284 on the dielectric layer 282. The dielectric layer 282 may surround the dielectric layer 284. For example, a bottom surface and sidewalls of the dielectric layer 284 are surrounded by the dielectric layer 282. The bottom surface of the dielectric layer 282 is in direct contact with the dielectric layers 270, 272, for example. A top surface of the dielectric layer 282 may be substantially coplanar with a top surface of the dielectric layer 284. The cap layer 280 has a material different from the dielectric wall DW and thus may serve as an etch stop layer during the etch process of the dielectric wall DW. For example, the material of the cap layer 280 is different from the dielectric layer 272. In some embodiments, the dielectric layers 282, 284 have different materials. The dielectric layer 282, 284 may include a dielectric material, such as silicon oxide, silicon nitride, SiON, SiC, SiCN, SiCO, SiCON, a high-k material, the like, or a combination thereof. The high-k material includes metal oxide, such as HfO2, HfSiO, HfSiON, HfTaO, HfSiO, HfZrO, zirconium oxide, aluminum oxide (Al2O3 or AlSiOx), titanium oxide, hafnium dioxide-alumina (HfO2-Al2O3) alloy, the like, or combinations thereof. The high-k material has a dielectric constant less than 8, less than 15, less than 20, or even more. A sidewall of the cap layer 280 may be substantially flush with a sidewall of the dielectric wall DW. For example, the cap layer 280 has a width substantially the same as the dielectric wall DW. In some embodiments, the dielectric wall DW to be etched is illustrated as having a multi-layer structure. However, the disclosure is not limited thereto. The dielectric wall DW to be etched may have a single structure without an etch stop layer therein as shown in FIG. 6 or any other suitable structure. In other words, the cap layer 280 may be formed on a top surface of any dielectric wall to be further etched.

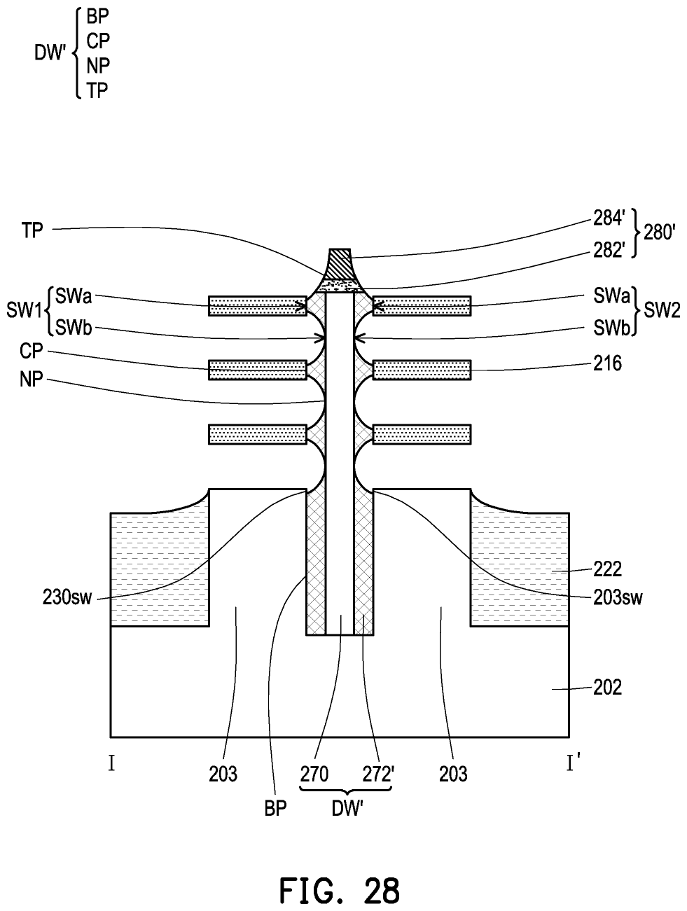

Referring to FIG. 28, an etch process such as an etch back process is performed on the dielectric wall DW, to form the dielectric wall DW′. During the etch process, the dielectric wall DW is partially removed to form the dielectric wall DW′ while the cap layer 280 may serve as a hard mask and thus remains intact. In some embodiments, as mentioned before, the dielectric layer 270 serves as an etch stop layer. In some embodiments, the formed dielectric wall DW′ has a structure similar to the dielectric wall DW′ of FIG. 23, and the difference lies in the topmost connecting portion CP has a different configuration from other connecting portions CP. This is because the dielectric wall DW′ is covered and protected by the cap layer 280 during the etch process. In some embodiments, the cap layer 280 is substantially not etched by the etch process. In some embodiments, after performing the etch process on the dielectric wall DW of FIG. 27, an additional etch process such as an etch back process is performed on the cap layer 280. Thus, the cap layer 280 is partially removed to form the cap layer 280′ including the dielectric layers 282′, 284′. For example, the side portion of the dielectric layer 282 is substantially removed by the additional etch process to expose the dielectric layer 284, and the side portion of the dielectric layer 284 may be partially removed. In some embodiments, the dielectric layer 282′ is interposed between the dielectric layer 284′ and the dielectric layers 270, 272′. The cap layer 280′ may have a curved sidewall. For example, the cap layer 280′ is mountain-shaped with a flat top and curved sidewalls. A horizontal dimension (e.g., width) of the cap layer 280′ decreases as the cap layer 280′ becomes far away from the substrate 202. In some embodiments, the cap layer 280′ is also referred to as a top portion TP of the dielectric wall DW′.

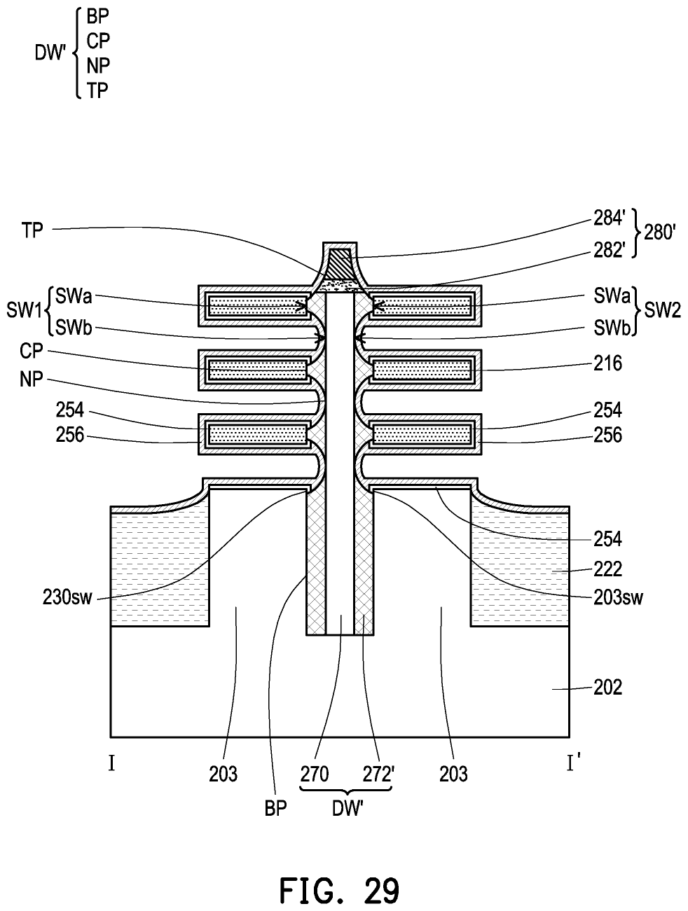

Referring to FIG. 29, an interfacial layer 254 is formed on the exposed surfaces of the nanosheets 216, and a gate dielectric layer 256 is formed on the exposed surfaces of the interfacial layer 254, the dielectric wall DW′ and the cap layer 280′. In some embodiments, the gate dielectric layer 256 conforms on the interfacial layer 254 on the nanosheets 216 and the dielectric wall DW′ (including the cap layer 280′). For example, the gate dielectric layer 256 is conformally formed on exposed surfaces of the top portion TP (e.g., cap layer 280′), the connecting portions CP and the bottom portion BP.

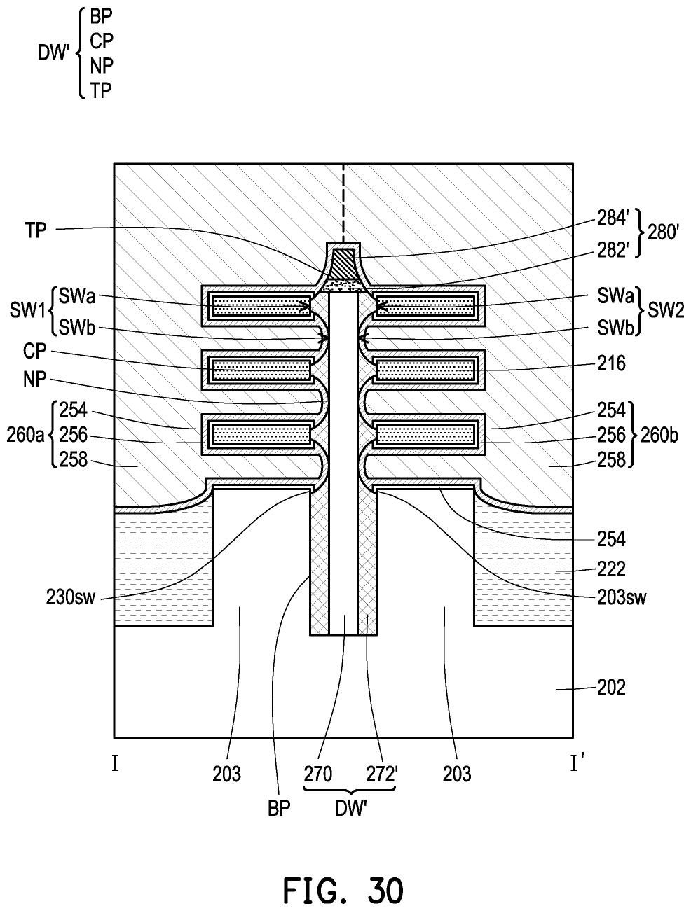

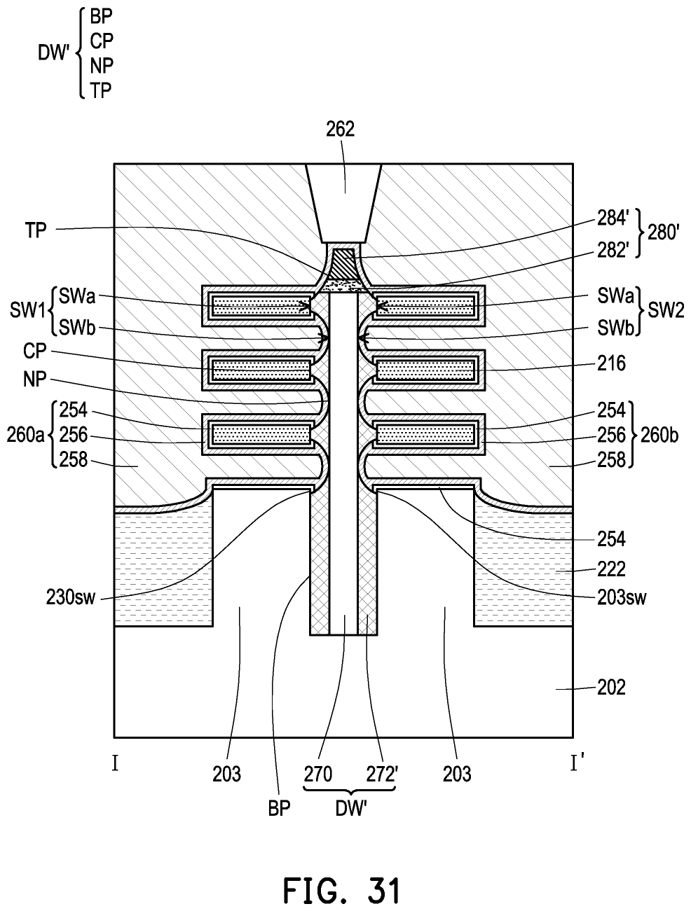

Referring to FIG. 30, a gate electrode 258 is formed on the gate dielectric layer 256 to surround each of the nanosheets 216, to form gate structures 260a, 260b. For example, the gate electrode 258 wraps around the nanosheets 216 in the channel regions with the gate dielectric layer 256 therebetween. Then, as shown in FIG. 31, at a specific location, a cut gate structure 262 may be formed between the gate structures 260a, 260b to separate the adjacent gate structures 260a, 260b.

In some embodiments, the dielectric wall has a cap layer thereon, and the cap layer serves as a mask during the etch process of the dielectric wall. Thus, the dielectric wall is prevented from being over-etched. Accordingly, the dielectric wall may have robust structure to provide isolation and support. In addition, since the dielectric wall has wavy sidewalls, the gate electrode may be further inserted into the gaps between the dielectric wall and the nanosheets. Accordingly, the nanosheets may be surrounded by the gate dielectric layer and the gate electrode with a larger area, and the effective channel width is increased. Thus, the weak corner turn-on effect is prevented or mitigated, and the performance of the semiconductor device is improved.

In accordance with some embodiments of the disclosure, a semiconductor device includes a substrate, a first stack of semiconductor nanosheets, a second stack of semiconductor nanosheets, a gate structure and a first dielectric wall. The substrate includes a first fin and a second fin. The first stack of semiconductor nanosheets is disposed on the first fin. The second stack of semiconductor nanosheets is disposed on the second fin. The gate structure wraps the first stack of semiconductor nanosheets and the second stack of semiconductor nanosheets. The first dielectric wall is disposed between the first stack of semiconductor nanosheets and the second stack of semiconductor nanosheets. The first dielectric wall includes at least one neck portion between adjacent two semiconductor nanosheets of the first stack.

In accordance with some embodiments of the disclosure, a semiconductor device includes a substrate, a first stack of semiconductor nanosheets, a second stack of semiconductor nanosheets, a gate structure and a dielectric wall. The substrate includes a first fin and a second fin. The first stack of semiconductor nanosheets is disposed on the first fin. The second stack of semiconductor nanosheets is disposed on the second fin. The gate structure wraps the first stack of semiconductor nanosheets and the second stack of semiconductor nanosheets. The dielectric wall is disposed between the first stack of semiconductor nanosheets and the second stack of semiconductor nanosheets. The dielectric wall includes a first wavy sidewall.

In accordance with some embodiments of the disclosure, a semiconductor device includes a substrate, a first stack of semiconductor nanosheets, a second stack of semiconductor nanosheets, a gate structure and a dielectric wall. The substrate includes a first fin and a second fin. The first stack of semiconductor nanosheets is disposed on the first fin. The second stack of semiconductor nanosheets is disposed on the second fin. The gate structure wraps the first stack of semiconductor nanosheets and the second stack of semiconductor nanosheets. The dielectric wall is disposed between the first stack of semiconductor nanosheets and the second stack of semiconductor nanosheets. The dielectric wall includes a dielectric pillar and a plurality of first dielectric portions on sidewalls of the dielectric pillar, and a material of the dielectric pillar is different from a material of the first dielectric portions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a first fin and a second fin;
a first stack of semiconductor nanosheets disposed on the first fin;
a second stack of semiconductor nanosheets disposed on the second fin;
a gate structure wrapping the first stack of semiconductor nanosheets and the second stack of semiconductor nanosheets; and
a first dielectric wall disposed between the first stack of semiconductor nanosheets and the second stack of semiconductor nanosheets, wherein the first dielectric wall comprises at least one neck portion between adjacent two semiconductor nanosheets of the first stack.

2. The semiconductor device of claim 1, wherein the first dielectric wall comprises a plurality of connecting portions, the at least one neck portion is disposed between the connecting portions, and first sides of the connecting portions are physically connected to the adjacent two semiconductor nanosheets of the first stack.

3. The semiconductor device of claim 2, wherein second sides opposite to the first sides of the connecting portions are physically connected to adjacent two semiconductor nanosheets of the second stack.

4. The semiconductor device of claim 2, wherein the at least one neck portion comprises a plurality of neck portions, and the neck portions and the connecting portions are alternately stacked on the substrate.

5. The semiconductor device of claim 4, wherein the first dielectric wall further comprises a top portion on the neck portions and the connecting portions, and a top surface of the top portion is higher than top surfaces of the first stack and the second stack.

6. The semiconductor device of claim 5, wherein a width of the top portion increases as the top portion becomes closer to the substrate.

7. The semiconductor device of claim 1, further comprising:
a first strained layer disposed on the first fin and abutting the first stack of semiconductor nanosheets;
a second strained layer disposed on the second fin and abutting the second stack of semiconductor nanosheets; and
a second dielectric wall disposed between the first strained layer and the second strained layer, wherein the second dielectric wall has a substantially vertical sidewall.

8. A semiconductor device, comprising:
a substrate comprising a first fin and a second fin;
a first stack of semiconductor nanosheets disposed on the first fin;
a second stack of semiconductor nanosheets disposed on the second fin;
a gate structure wrapping the first stack of semiconductor nanosheets and the second stack of semiconductor nanosheets; and
a dielectric wall disposed between the first stack of semiconductor nanosheets and the second stack of semiconductor nanosheets, wherein the dielectric wall comprises a first wavy sidewall.

9. The semiconductor device of claim 8, wherein the first wavy sidewall is in direct contact with the first stack of semiconductor nanosheets.

10. The semiconductor device of claim 9, wherein the dielectric wall further comprises a second wavy sidewall opposite to the first wavy sidewall, and the second wavy sidewall is in direct contact with the second stack of semiconductor nanosheets.

11. The semiconductor device of claim 8, wherein the first wavy sidewall comprises a plurality of first portions and a plurality of second portions alternately and vertically arranged, the first portions are physically connected to the first stack of semiconductor nanosheets, and the second portions are physically connected to the gate structure.

12. The semiconductor device of claim 11, wherein a height of one of the first portions is substantially the same as a height of a respective semiconductor nanosheet of the first stack directly connecting to the one of the first portions.

13. The semiconductor device of claim 11, wherein a height of one of the first portions is smaller than or larger than a height of a respective semiconductor nanosheet of the first stack directly connecting to the one of the first portions.

14. The semiconductor device of claim 8, wherein the gate structure is inserted between the first fin and the dielectric wall.

15. The semiconductor device of claim 8, wherein in a cross-sectional view, the dielectric wall is physically separated from the first stack of semiconductor nanosheets by the gate structure.

16. A semiconductor device, comprising:
a substrate comprising a first fin and a second fin;
a first stack of semiconductor nanosheets disposed on the first fin;
a second stack of semiconductor nanosheets disposed on the second fin;
a gate structure wrapping the first stack of semiconductor nanosheets and the second stack of semiconductor nanosheets; and
a dielectric wall disposed between the first stack of semiconductor nanosheets and the second stack of semiconductor nanosheets, wherein the dielectric wall comprises a dielectric pillar and a plurality of first dielectric portions on sidewalls of the dielectric pillar, and a material of the dielectric pillar is different from a material of the first dielectric portions.

17. The semiconductor device of claim 16, wherein the dielectric pillar is an etch stop layer.

18. The semiconductor device of claim 16, wherein a width of the dielectric pillar is substantially constant, and a width of the first dielectric portion decreases as the first dielectric portion becomes far away from the semiconductor nanosheet directly connected to the first dielectric portion.

19. The semiconductor device of claim 16, further comprising a second dielectric portion on a top surface of the dielectric pillar, wherein a width of the second dielectric portion decreases as the second dielectric portion becomes far away from the dielectric pillar.

20. The semiconductor device of claim 16, wherein the dielectric wall further comprises a cap layer on the dielectric pillar and the first dielectric portions, and a material of the cap layer is different from the first dielectric portions.
